(19) United States
(12) Patent Application Publication
(10) Pub. No.: US 2025/0238358 A1
(43) Pub. Date: Jul. 24, 2025

(54) METHOD OF OPERATING NONVOLATILE MEMORY DEVICE AND NONVOLATILE MEMORY DEVICE

(71) Applicant: Samsung Electronics Co., Ltd., Suwon-si (KR)

(72) Inventors: Yonglae KIM, Suwon-si (KR); Jaeyong JEONG, Suwon-si (KR)

(73) Assignee: Samsung Electronics Co., Ltd., Suwon-si (KR)

(21) Appl. No.: 18/908,933

(22) Filed: Oct. 8, 2024

(30) Foreign Application Priority Data
Jan. 23, 2024 (KR) 10-2024-0009901

(51) Int. Cl. G06F 12/02

(52) U.S. Cl. CPC G06F 12/0223

(57) ABSTRACT

In a method of operating a nonvolatile memory device that includes a memory block, a voltage level of an external voltage from an external memory controller is detected while receiving a read command sequence from the external memory controller, each of a plurality of word-lines coupled to the plurality of memory cells is set up to a respective target level during a word-line set-up period while adaptively adjusting a ramping period during which a read pass voltage ramps to a target level based on the detected voltage level, a sensing operation is performed on target memory cells by applying a read voltage to a selected word-line coupled to the target memory cells, among the plurality of word-lines while applying the read pass voltage to unselected word-lines among the plurality of word-lines during a sensing period, and sensed data obtained by the sensing operation is outputted.

### CROSS-REFERENCE TO RELATED APPLICATION

This US application claims priority under 35 USC § 119 to Korean Patent Application No. 10-2024-0009901, filed on Jan. 23, 2024, in the Korean Intellectual Property Office (KIPO), the disclosure of which is incorporated herein by reference in its entirety.

### BACKGROUND

Example embodiments generally relate to memory devices, and more particularly to methods of operating nonvolatile memory devices and nonvolatile memory devices performing the same.

Semiconductor memory devices for storing data may be classified into volatile memory devices and nonvolatile memory devices. Volatile memory devices, such as dynamic random access memory (DRAM) devices, are typically configured to store data by charging or discharging capacitors in memory cells, and lose the stored data when power is off. Nonvolatile memory devices, such as flash memory devices, may maintain stored data even though power is off. Volatile memory devices are widely used as main memories of various apparatuses, while nonvolatile memory devices are widely used for storing program codes and/or data in various electronic devices, such as computers, mobile devices, etc.

Recently, nonvolatile memory devices of three-dimensional structure such as a vertical NAND memory devices have been developed to increase integration degree and memory capacity of the nonvolatile memory devices. The nonvolatile memory devices generate word-line voltages based on an external voltage.

### SUMMARY

Some example embodiments may provide methods of operating a nonvolatile memory device, capable of maintaining a channel boosting level when a voltage level of an external voltage varies.

Some example embodiments may provide nonvolatile memory devices capable of maintaining a channel boosting level when a voltage level of an external voltage varies.

According to example embodiments, in a method of operating a nonvolatile memory device that includes at least one memory block including a plurality of cell strings, each of the plurality of cell strings including a string selection transistor, a plurality of memory cells, and a ground selection transistor connected in series in a vertical direction between a bit-line and a common source line, a voltage level of an external voltage provided from an external memory controller is detected while receiving a read command sequence from the external memory controller, each of a plurality of word-lines coupled to the plurality of memory cells is set up to a respective target level during a word-line set-up period while adaptively adjusting a ramping period during which a read pass voltage ramps to a target level based on the detected voltage level, a sensing operation is performed on target memory cells by applying a read voltage to a selected word-line coupled to the target memory cells, among the plurality of word-lines while applying the read pass voltage to unselected word-lines among the plurality of word-lines during a sensing period, and sensed data obtained by the sensing operation is outputted.

According to example embodiments, a nonvolatile memory device includes a memory cell array and a control circuit. The memory cell array includes at least one memory block including a plurality of cell strings, each of the plurality of cell strings including a string selection transistor, a plurality of memory cells, and a ground selection transistor connected in series in a vertical direction between a bit-line and a common source line. The control circuit controls a read operation by detecting a voltage level of an external voltage provided from an external memory controller while receiving a read command sequence from the external memory controller, setting up each of a plurality of word-lines coupled to the plurality of memory cells to a respective target level during a word-line set-up period while adaptively adjusting a ramping period during which a read pass voltage ramps to a target level based on the detected voltage level, performing a sensing operation on target memory cells by applying a read voltage to a selected word-line coupled to the target memory cells, among the plurality of word-lines while applying the read pass voltage to unselected word-lines among the plurality of word-lines during a sensing period and outputting sensed data obtained by the sensing operation.

According to example embodiments, a nonvolatile memory device includes a memory cell array, a voltage generation circuit, an address decoder and a control circuit. The memory cell array includes at least one memory block including a plurality of cell strings, each of the plurality of cell strings including a string selection transistor, a plurality of memory cells, and a ground selection transistor connected in series in a vertical direction between a bit-line and a common source line. The voltage generation circuit generates word-line voltages including a read voltage, a read pass voltage and a pre-pulse based on control signals. The address decoder provides the word-line voltages to the at least one memory block based on a row address. The control circuit controls a read operation by detecting a voltage level of an external voltage provided from an external memory controller while receiving a read command sequence from the external memory controller, setting up each of a plurality of word-lines coupled to the plurality of memory cells to a respective target level during a word-line set-up period while adaptively adjusting a ramping period during which the read pass voltage ramps to a target level by adjusting a time period of applying the pre-pulse, based on the detected voltage level, performing a sensing operation on target memory cells by applying the read voltage to a selected word-line coupled to the target memory cells, among the plurality of word-lines while applying the read pass voltage to unselected word-lines among the plurality of word-lines during a sensing period and outputting sensed data obtained by the sensing operation.

Therefore, in the nonvolatile memory device and a method of operating the nonvolatile memory device, a boosting potential of a channel may be maintained constantly after pre-pulse is applied by adaptively adjusting a period of applying the pre-pulse to the unselected word-lines based on a voltage level of the external voltage. Accordingly, hot carrier injection may be prevented or reduced and the string selection transistor or the ground selection transistor may be prevented or reduced from being degraded.

### BRIEF DESCRIPTION OF THE DRAWINGS

Illustrative, non-limiting example embodiments will be more clearly understood from the following detailed description in conjunction with the accompanying drawings.

FIG. 1 is a flow chart illustrating a method of operating a nonvolatile memory device according to example embodiments.

FIG. 2 is a flow chart illustrating an example operation of setting up each of the plurality of word-lines to a respective target level in the method of FIG. 1 according to example embodiments.

FIG. 3 illustrates an example operation of increasing a voltage of each of the unselected word-lines to the read pass voltage in FIG. 2 according to example embodiments.

FIG. 4 is a timing diagram illustrating a method of operating a nonvolatile memory device according to example embodiments.

FIG. 5 illustrates an example operation of adjusting a ramping period during which a read pass voltage ramps to a target level based on the detected voltage level in the method of FIG. 1 according to example embodiments.

FIG. 6 is a block diagram illustrating a memory system according to example embodiments.

FIG. 7 is a block diagram illustrating an example of the memory controller in the memory system of FIG. 6 according to example embodiments.

FIG. 8 is a block diagram illustrating an example of the nonvolatile memory device in the memory system of FIG. 6 according to example embodiments.

FIG. 9 schematically illustrates a structure of the nonvolatile memory device of FIG. 8 according to example embodiments.

FIG. 10 is a block diagram illustrating an example of the memory cell array in FIG. 8 according to example embodiments.

FIG. 11 is a circuit diagram illustrating one of the memory blocks of FIG. 10.

FIG. 12 illustrates an example of a structure of a cell string CS in the memory block of FIG. 11.

FIG. 13 is a schematic diagram of a connection of the memory cell array to the page buffer circuit in FIG. 8, according to example embodiments.

FIG. 14 is a block diagram illustrating an example of the voltage detector in the nonvolatile memory device of FIG. 8 according to example embodiments.

FIG. 15 is a block diagram illustrating an example of the control circuit in the nonvolatile memory device of FIG. 8 according to example embodiments.

FIG. 16 is a block diagram illustrating an example of the address decoder in the nonvolatile memory device of FIG. 8 according to example embodiments.

FIG. 17 is a block diagram illustrating an example of the voltage generator in the nonvolatile memory device of FIG. 8 according to example embodiments.

FIG. 18 is a block diagram illustrating an example of the high voltage generator in the voltage generation circuit of FIG. 17 according to example embodiments.

FIG. 19 is a graph showing a threshold voltage distributions of memory cells in FIG. 11.

FIG. 20A is a timing diagram illustrating an example operation of the voltage generation circuit of FIG. 17 according to example embodiments.

FIG. 20B is a timing diagram illustrating an example operation of the address decoder of FIG. 16 according to example embodiments.

FIG. 21 is a timing diagram illustrating an example operation of the memory system of FIG. 6.

FIG. 22 is a timing diagram schematically illustrating an example of a read operation of the nonvolatile memory device of FIG. 8 according to example embodiments.

FIG. 23 is a block diagram illustrating a nonvolatile memory device according to example embodiments.

FIG. 24 illustrates a first plane and a second plane of the nonvolatile memory device of FIG. 23 according to example embodiments.

FIG. 25 is a cross-sectional view of a nonvolatile memory device according to some example embodiments.

FIG. 26 is a diagram illustrating a manufacturing process of a stacked semiconductor device according to some example embodiments.

FIG. 27 is a block diagram illustrating an electronic system including a semiconductor device according to some example embodiments.

### DETAILED DESCRIPTION OF THE EMBODIMENTS

Various example embodiments will be described more fully hereinafter with reference to the accompanying drawings, in which some example embodiments are shown.

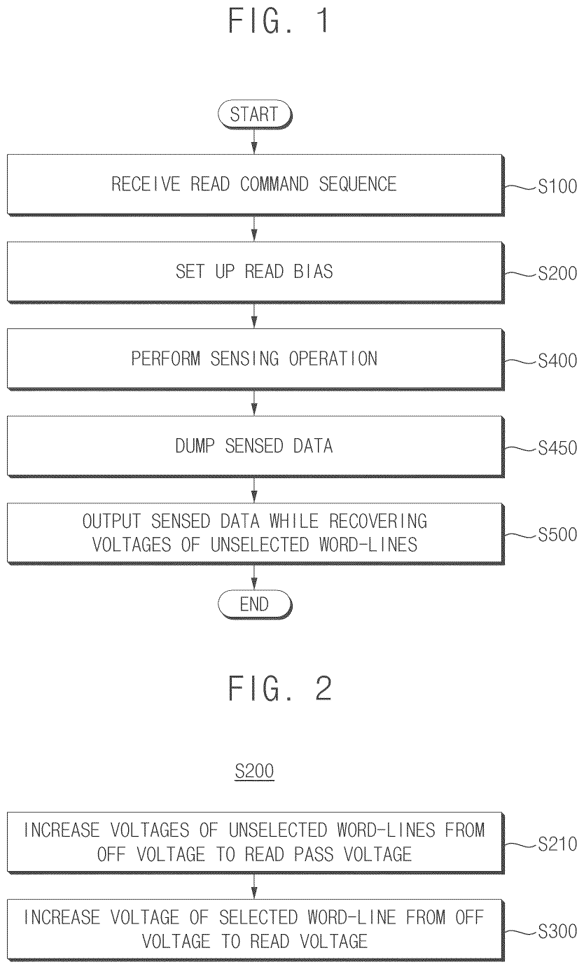

FIG. 1 is a flow chart illustrating a method of operating a nonvolatile memory device according to example embodiments.

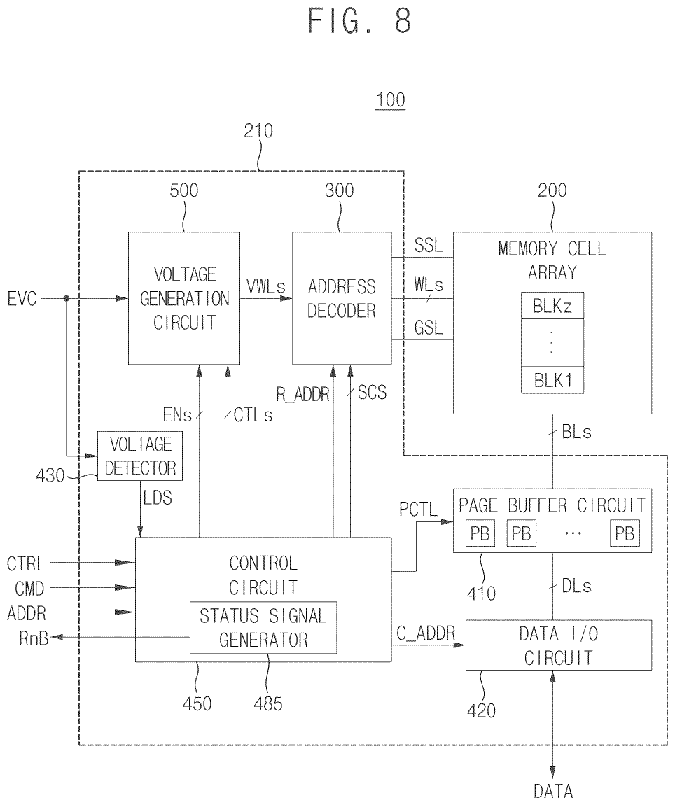

FIG. 1 illustrates a method of operating a nonvolatile memory device 100 including at least one memory block which includes a plurality of cell strings, where each cell string includes a string selection transistor, a plurality of memory cells and a ground selection transistor connected in series and disposed in a vertical direction between a bit-line and a common source line as will be described with reference to FIGS. 8 through 22.

Referring to FIG. 1, according to the method, a voltage level of an external voltage provided from an external memory controller is detected while receiving a read command sequence from the external memory controller (operation S100).

A voltage generation circuit in the nonvolatile memory device sets up each of a plurality of word-lines coupled to the plurality of memory cells to a respective target level during a word-line set-up period while adaptively adjusting a ramping period during which a read pass voltage ramps to a target level based on the detected voltage level (operation S200). That is, the voltage generation circuit increases a voltage of each of unselected word-lines from an off voltage to a read pass voltage with adaptively adjusting a period of increasing the voltage of each of unselected word-lines while setting up a read voltage and the read pass voltage applied to the selected word-line and the unselected word-lines, respectively.

A sensing operation is performed on target memory cells by applying the read voltage to the selected word-line coupled to the target memory cells, among the plurality of word-lines while applying the read pass voltage to the unselected word-lines among the plurality of word-lines during a sensing period (operation S400).

Sensed data latched in a page buffer circuit is dumped to a data input/output (I/O) circuit connected to the page buffer circuit during a data dump period (operation S450).

A voltage level of the unselected word-lines to which the read pass voltage is applied is recovered to the off voltage while outputting the sensed data obtained by the sensing operation to the external memory controller during a discharge period of a recovery period (operation S500).

The nonvolatile memory device generates the read pass voltage and the read voltage based on the external voltage. The conventional nonvolatile memory device increases a voltage level of the read pass voltage to a target level by applying a pre-pulse to the unselected word-lines during a pre-determined (or, alternatively, desired or selected) time interval without regard to a variation of the external voltage. Therefore, when the voltage level of the external voltage decreases, a ramping slope of the read pass voltages also decreases and thus, a boosting potential of a channel increases after the pre-pulse is applied. When the boosting potential of the channel increases, a leakage current input through a bit-line or a common source line is injected to a string selection transistor or a ground selection transistor as hot carrier injection (HCI). Accordingly, a threshold voltage of the string selection transistor or the ground selection transistor may increase and the string selection transistor or the ground selection transistor may be degraded.

For example, according to some example embodiments, there may be an increase in speed, accuracy, longevity and/or power efficiency of the host system based on the above methods. Therefore, the improved devices and methods overcome the deficiencies of the conventional devices and methods of operating memory devices, while reducing resource consumption (e.g., processing capability, power), improving data accuracy, and resource allocation (e.g., latency). For example, by providing the described pre-pulse and associated features according to some example embodiments, the memory device may improve longevity while providing more consistent access to data.

However, in the method of operating a nonvolatile memory device according to example embodiments, a boosting potential of a channel may be maintained constantly after pre-pulse is applied by adaptively adjusting a period of applying the pre-pulse to the unselected word-lines based on a voltage level of the external voltage. Therefore, HCI may be prevented or reduced and the string selection transistor or the ground selection transistor may be prevented or reduced from being degraded.

FIG. 2 is a flow chart illustrating an example operation of setting up each of the plurality of word-lines to a respective target level in the method of FIG. 1 according to example embodiments.

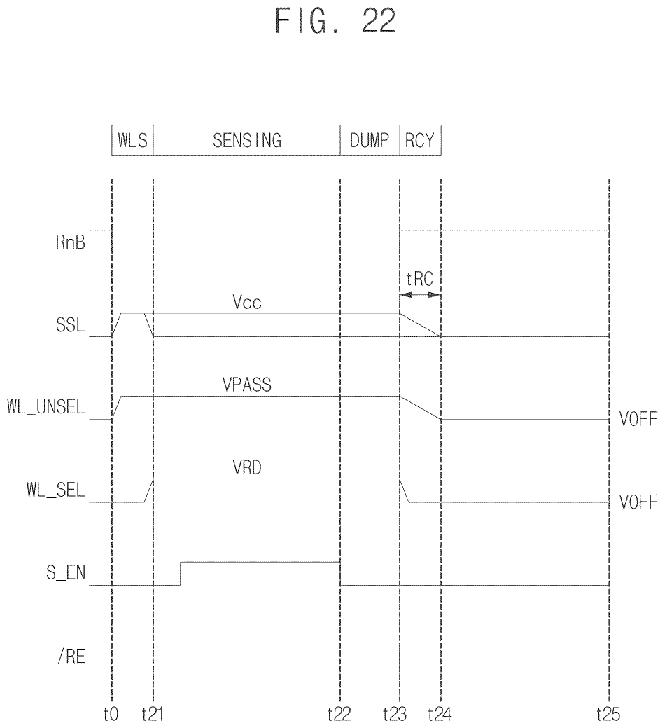

Referring to FIG. 2, for setting up each of the plurality of word-lines to a respective target level (operation S200), a voltage of each of the unselected word-lines is increased from an off voltage VOFF to a read pass voltage VPASS during the word-line set-up period (operation S210) and a voltage of the selected word-line is increased from the off voltage VOFF to a read voltage VRD as will be described with reference to FIG. 22.

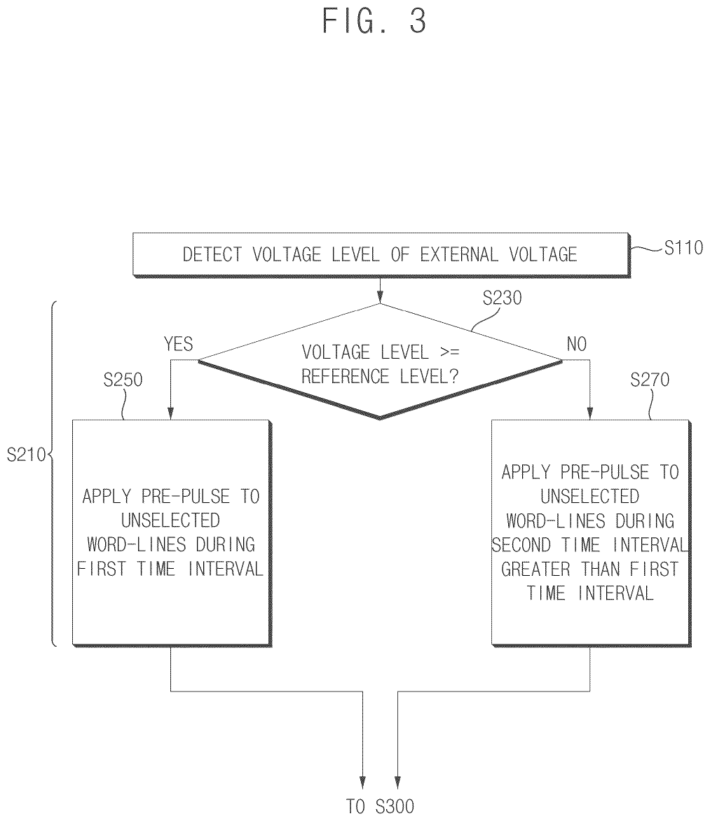

FIG. 3 illustrates an example operation of increasing a voltage of each of the unselected word-lines to the read pass voltage in FIG. 2 according to example embodiments.

Referring to FIG. 3, the voltage level of the external voltage is detected during the read sequence is being received (operation S110). The operation of detecting the external voltage (S110) may be included in the operation S100 in FIG. 1.

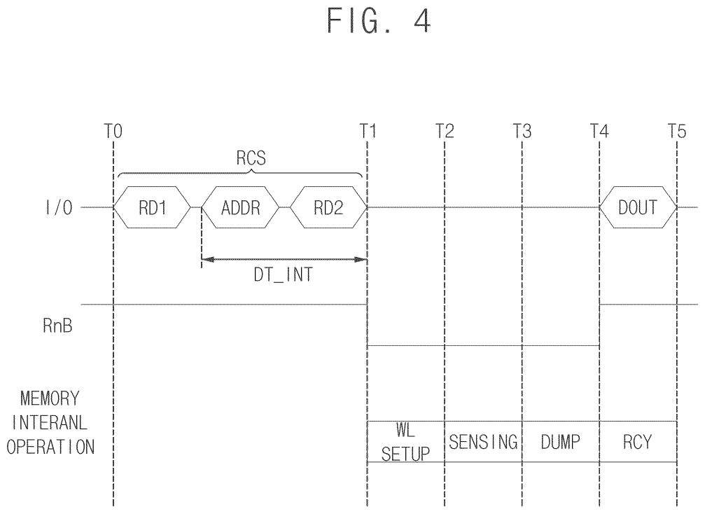

For increasing a voltage of each of the unselected word-lines to the read pass voltage (operation S210), it is determined whether the detected voltage level is equal to or greater than at least one reference level by comparing the detected voltage level with the at least one reference level (operation S230) as will be described with reference to FIGS. 4, 5 and 7.

When the detected voltage level is equal to or greater than the at least one reference level (YES in S230), the pre-pulse is applied to the unselected word-lines during a first time interval in response to the detected voltage level being equal to or greater than the at least one reference level (operation S250). When the detected voltage level is smaller than the at least one reference level (NO in S230), the pre-pulse is applied to the unselected word-lines during a second time interval greater than the first time interval, in response to the detected voltage level being smaller than the at least one reference level (operation S270). Therefore, when the voltage level of the external voltage varies, a boosting potential of a channel may be maintained constantly after pre-pulse is applied.

FIG. 4 is a timing diagram illustrating a method of operating a nonvolatile memory device according to example embodiments.

Referring to FIG. 4, the nonvolatile memory device may receive a read command sequence RCS including a first read command RD1, an address ADDR and a second read command RD2 from an external memory controller during a time interval T0˜T1, and may detect a voltage level of an external voltage provided from the external memory controller during a time interval DT_INT in which the nonvolatile memory device receives the address ADDR and the second read command RD2. When reception of the read command sequence RCS is completed, the nonvolatile memory device may transition a status signal RnB to a low level (busy state). The nonvolatile memory device may be responsive to a status read command (for example, the second read command RD2) received through input/output (I/O) terminals to transmit the busy state to the external memory controller.

The nonvolatile memory device may generate a word-line voltage to be provided to a selected memory region in response to the read command, and the word-line voltage may be applied to the selected memory region. This operation may be a word-line setup period WL SETUP corresponding to a time interval T1 to T2 in FIG. 4. Then, the nonvolatile memory device may sense and latch cells of the selected memory region. This operation may be a sensing period SENSING corresponding to a time interval T2 to T3 in FIG. 4. The sensed data may be dumped to a data I/O circuit in the nonvolatile memory device. This operation may be a dump period DUMP corresponding to a time interval T3 to T4 in FIG. 4.

The nonvolatile memory device may perform a recovery operation at a point of time T4 when dumping of the sensing data to the data I/O circuit is completed. Here, the recovery operation RCY may be performed to discharge a bulk, word-lines, bit-lines, selection lines, a common source line, etc. associated with the selected memory cells. Also, the nonvolatile memory device may set the status signal to a high level (ready state) at a point of time T4 when dumping of the sensed data to the data I/O circuit is completed. Data output Dout of the nonvolatile memory device to the external memory controller may be possible from a point of time when the status signal transitions to a high level.

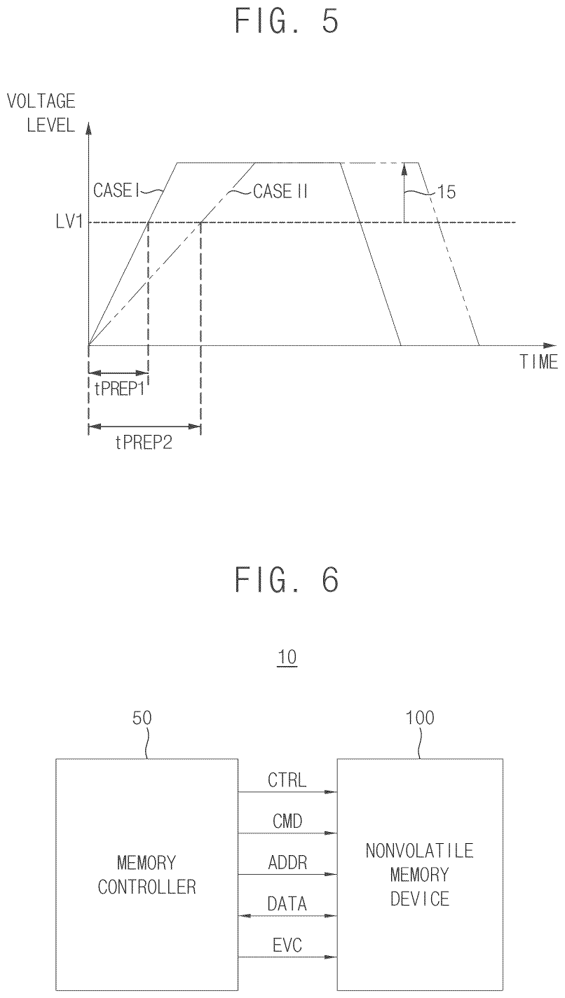

FIG. 5 illustrates an example operation of adjusting a ramping period during which a read pass voltage ramps to a target level based on the detected voltage level in the method of FIG. 1 according to example embodiments.

Referring to FIG. 5, the detected voltage level is compared with the at least one reference level. When the detected voltage level is equal to or greater than the at least one reference level (CASE1), each of voltages of the unselected word-lines are increased to a first level LV1 by applying the pre-pulse to the unselected word-lines during a first time interval tPREP1. When the detected voltage level is smaller than the at least one reference level (CASE2), each of voltages of the unselected word-lines are increased to the first level LV1 by applying the pre-pulse to the unselected word-lines during a second time interval tPREP2 greater than the first time interval tPREP1. When the voltage level of the external voltage varies, a booting potential of a channel of a cell string including the unselected word-lines may be may be maintained constantly as a reference numeral 15 indicates after the pre-pulse is applied, and thus the HCI may be prevented or reduced.

FIG. 6 is a block diagram illustrating a memory system according to example embodiments.

Referring to FIG. 6, a memory system 10 may include a memory controller 50 and at least one nonvolatile memory device 100. The memory system may be referred to as a storage device.

In example embodiments, each of the memory controller 50 and the nonvolatile memory device 100 may be provided with the form of a chip, a package, or a module. Alternatively, the memory controller 50 and the nonvolatile memory device 100 may be packaged into one of various packages.

The nonvolatile memory device 100 may perform an erase operation, a program operation or a write operation and a read operation under control of the memory controller 50. The nonvolatile memory device 100 may receive a command CMD, an address ADDR and data DATA through input/output lines from the memory controller 50 for performing such operations. In addition, the nonvolatile memory device 100 may receive a control signal CTRL through a control line from the memory controller 50. In addition, the nonvolatile memory device 100 may receive an external voltage EVC through a power line from the memory controller 50.

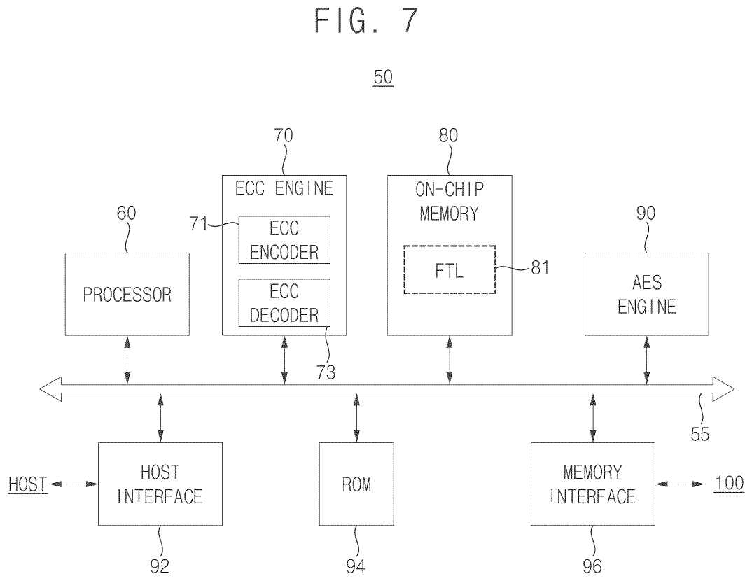

FIG. 7 is a block diagram illustrating an example of the memory controller in the memory system of FIG. 6 according to example embodiments.

Referring to FIG. 7, the memory controller 50 may include a processor 60, an error correction code (ECC) engine 70, an on-chip memory 80, an advanced encryption standard (AES) engine 90, a host interface 92, a ROM 94 and a memory interface 96 which are connected via a bus 55.

The processor 60 may control an overall operation of the memory controller 50. The processor 60 may control the ECC engine 70, the on-chip memory 80, the AES engine 90, the host interface 92, the ROM 94 and the memory interface 96. The processor 60 may include one or more cores (e.g., a homogeneous multi-core or a heterogeneous multi-core). The processor 60 may be or include, for example, at least one of a central processing unit (CPU), an image signal processing unit (ISP), a digital signal processing unit (DSP), a graphics processing unit (GPU), a vision processing unit (VPU), and a neural processing unit (NPU). The processor 60 may execute various application programs (e.g., a flash translation layer (FTL) 81 and firmware) loaded onto the on-chip memory 80.

The on-chip memory 80 may store various application programs that are executable by the processor 60. The on-chip memory 80 may operate as a cache memory adjacent to the processor 60. The on-chip memory 80 may store a command, an address, and data to be processed by the processor 60 or may store a processing result of the processor 60. The on-chip memory 80 may be, for example, a storage medium or a working memory including a latch, a register, a static random access memory (SRAM), a dynamic random access memory (DRAM), a thyristor random access memory (TRAM), a tightly coupled memory (TCM), etc.

The processor 60 may execute the FTL 81 loaded onto the on-chip memory 80. The FTL 81 may be loaded onto the on-chip memory 80 as firmware or a program stored in the nonvolatile memory device 100. The FTL 81 may manage mapping between a logical address provided from a host and a physical address of the nonvolatile memory device 100 and may include an address mapping table manager managing and updating an address mapping table. The FTL 81 may further perform a garbage collection operation, a wear leveling operation, and the like, as well as the address mapping described above. The FTL 81 may be executed by the processor 60 for addressing one or more of the following aspects of the nonvolatile memory device 100: overwrite- or in-place write-impossible, a life time of a memory cell, a limited number of program-erase (PE) cycles, and an erase speed slower than a write speed.

Memory cells of the nonvolatile memory device 100 may have the physical characteristic that a threshold voltage distribution varies due to causes, such as a program elapsed time, a temperature, program disturbance, read disturbance and etc. For example, data stored at the nonvolatile memory device 100 becomes erroneous due to the above causes.

The memory controller 50 may utilize a variety of error correction techniques to correct such errors. For example, the memory controller 50 may include the ECC engine 70. The ECC engine 70 may correct errors which occur in the data stored in the nonvolatile memory device 100. The ECC engine 70 may include an ECC encoder 71 and an ECC decoder 73. The ECC encoder 71 may perform an ECC encoding operation on data to be stored in the nonvolatile memory device 100. The ECC decoder 73 may perform an ECC decoding operation on data read from the nonvolatile memory device 100.

The ROM 94 may store a variety of information, needed for the memory controller 50 to operate, in firmware.

The AES engine 90 may perform at least one of an encryption operation and a decryption operation on data input to the memory controller 50 by using a symmetric-key algorithm. Although not illustrated in detail, the AES engine 90 may include an encryption module and a decryption module. For example, the encryption module and the decryption module may be implemented as separate modules. For another example, one module capable of performing both encryption and decryption operations may be implemented in the AES engine 90.

The memory controller 50 may communicate with a host through the host interface 92. For example, the host interface 94 may include Universal Serial Bus (USB), Multimedia Card (MMC), embedded-MMC, peripheral component interconnection (PCI), PCI-express, Advanced Technology Attachment (ATA), Serial-ATA, Parallel-ATA, small computer small interface (SCSI), enhanced small disk interface (ESDI), Integrated Drive Electronics (IDE), Mobile Industry Processor Interface (MIPI), Nonvolatile memory express (NVMe), Universal Flash Storage (UFS), and etc. The memory controller 50 may communicate with the nonvolatile memory device 100 through the memory interface 96.

FIG. 8 is a block diagram illustrating an example of the nonvolatile memory device in the memory system of FIG. 6 according to example embodiments.

Referring to FIG. 8, the nonvolatile memory device 100 may include a memory cell array 200 and a peripheral circuit 210. The peripheral circuit 210 may include a page buffer circuit 410, a data I/O circuit 420, a voltage detector 430, a control circuit 450, a voltage generation circuit 500 and an address decoder 300. Although not illustrated in FIG. 8, the peripheral circuit 210 may further include an I/O interface, a column logic, a pre-decoder, a temperature sensor, a command decoder, etc.

The memory cell array 200 may be coupled to the address decoder 300 through a string selection line SSL, a plurality of word-lines WLs, and a ground selection line GSL. In addition, the memory cell array 200 may be coupled to the page buffer circuit 410 through a plurality of bit-lines BLs. The memory cell array 200 may include a plurality of nonvolatile memory cells coupled to the plurality of word-lines WLs and the plurality of bit-lines BLs.

The memory cell array 200 may include a plurality of memory blocks BLK1 through BLKz, and each of the memory blocks BLK1 through BLKz may have a three-dimensional (3D) structure. Here, z is an integer greater than two. The memory cell array 200 may include a plurality of vertical cell strings and each of the vertical cell strings includes a plurality of memory cells stacked with respect to each other.

The control circuit 450 may receive the command CMD, the address ADDR, and the control signal CTRL from the memory controller 50 and may control an erase loop, a program loop and a read operation of the nonvolatile memory device 100. The program loop may include a program operation and a program verification operation and the erase loop may include an erase operation and an erase verification operation.

In example embodiments, the control circuit 450 may generate control signals CTLs and enable signals ENs, which are used for controlling the voltage generation circuit 500, based on the command CMD, may generate a page buffer control signal PCTL for controlling the page buffer circuit 410, may generate switching control signals SCS for controlling the address decoder 300 and may generate a row address R_ADDR and a column address C_ADDR based on the address ADDR. The control circuit 450 may provide the control signals CTLs and the enable signals ENs to the voltage generation circuit 500 and may provide the page buffer control signal PCTL to the page buffer circuit 410.

In addition, the control circuit 450 may provide the row address R_ADDR and the switching control signals SCS to the address decoder 300 and provide the column address C_ADDR to the data I/O circuit 420. The control circuit 450 may include a status generator 485 and the status generator 485 may generate the status signal RnB indicating an operating status of the nonvolatile memory device 100. The status signal RnB may be referred to as a ready/busy signal because of the status signal RnB indicates either busy state or a ready state of the nonvolatile memory device 100.

The address decoder 300 may be coupled to the memory cell array 200 through the string selection line SSL, the plurality of word-lines WLs, and the ground selection line GSL. During program operation or read operation, the address decoder 300 may determine one of the plurality of word-lines WLs as a selected word-line based on the row address R_ADDR and may determine rest of the plurality of word-lines WLs except the selected word-line as unselected word-lines.

The voltage generation circuit 500 may generate word-line voltages VWLs associated with operations of the nonvolatile memory device 100 using the external voltage EVC provided from the memory controller 50 based on control signals CTLs and the enable signals ENs from the control circuit 450. The word-line voltages VWLs may include a program voltage, a pre-pulse, a read voltage, a pass voltage, an erase verification voltage, or a program verification voltage. The word-line voltages VWLs may be applied to the plurality of word-lines WLs through the address decoder 300.

For example, during the erase operation, the voltage generation circuit 500 may apply erase voltage to a channel of cell strings of a selected memory block and may apply a ground voltage to all word-lines of the selected memory block. During the erase verification operation, the voltage generation circuit 500 may apply erase verification voltage to all word-lines of the selected memory block or may apply the erase verification voltage to the word-lines of the selected memory block by word-line basis.

For example, during the program operation, the voltage generation circuit 500 may apply a program voltage to the selected word-line and may apply a program pass voltage to the unselected word-lines. In addition, during the program verification operation, the voltage generation circuit 500 may apply a program verification voltage to the selected word-line and may apply a verification pass voltage to the unselected word-lines. In addition, during the read operation, the voltage generation circuit 500 may apply a read voltage to the selected word-line and may apply a read pass voltage to the unselected word-lines.

The page buffer circuit 410 may be coupled to the memory cell array 200 through the plurality of bit-lines BLs. The page buffer circuit 410 may include a plurality of page buffers PB. The page buffer circuit 410 may temporarily store data to be programmed in a selected page or data read out from the selected page of the memory cell array 200.

In example embodiments, page buffer units included in each of the plurality of page buffers PB (for example, first through n-th page buffer units PBU1 through PBUn in FIG. 13) and cache latches included in each of the plurality of page buffers PB (for example, first through n-th cache latches CL1 through CLn in FIG. 13) may be apart from each other, and have separate structures. Accordingly, the degree of freedom of wirings on the page buffer units may be improved, and the complexity of a layout may be reduced. In addition, because the cache latches are adjacent to data I/O lines, the distance between the cache latches and the data I/O lines may be reduced, and thus, data I/O speed may be improved.

The voltage detector 430 may detect a voltage level of the external voltage EVC and may provide the control circuit 450 with a level detection signal LDS indicating a detected voltage level during which the nonvolatile memory device 100 receives the read command sequence from the memory controller 50. The voltage detector 430 may compare the detected voltage level with at least one reference level and may provide the control circuit 450 with a level detection signal LDS indicating a result of the comparison.

The control circuit 450, in response to the read command sequence, may control a read operation by setting up each of a plurality of word-lines coupled to the plurality of memory cells to a respective target level during a word-line set-up period while adaptively adjusting a ramping period during which a read pass voltage ramps to a target level based on the detected voltage level, performing a sensing operation on target memory cells by applying a read voltage to a selected word-line coupled to the target memory cells, among the plurality of word-lines while applying the read pass voltage to unselected word-lines among the plurality of word-lines during a sensing period and outputting a sensed data obtained by the sensing operation.

The data I/O circuit 420 may be coupled to the page buffer circuit 410 through a plurality of data lines DLs. During the program operation, the data I/O circuit 420 may receive program data DATA from the memory controller 50 and may provide the program data DATA to the page buffer circuit 410 based on the column address C_ADDR received from the control circuit 450. During the read operation, the data I/O circuit 420 may provide read data DATA to the memory controller 50 based on the column address C_ADDR received from the control circuit 450.

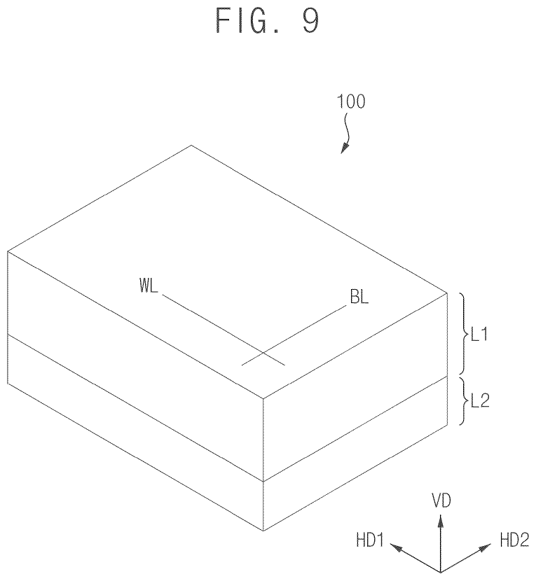

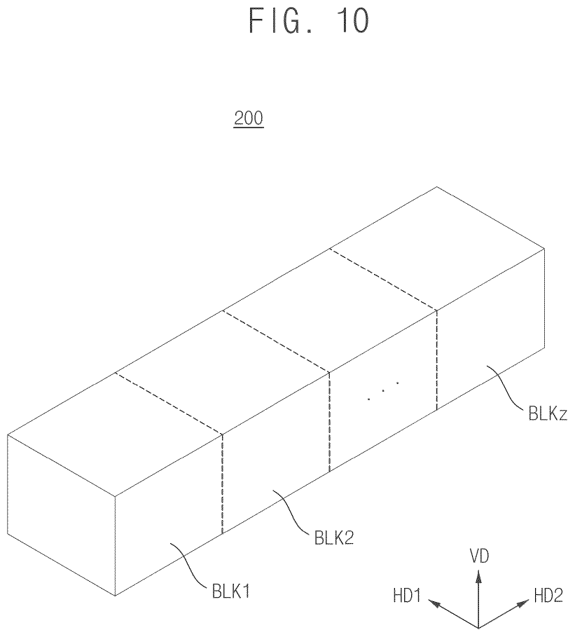

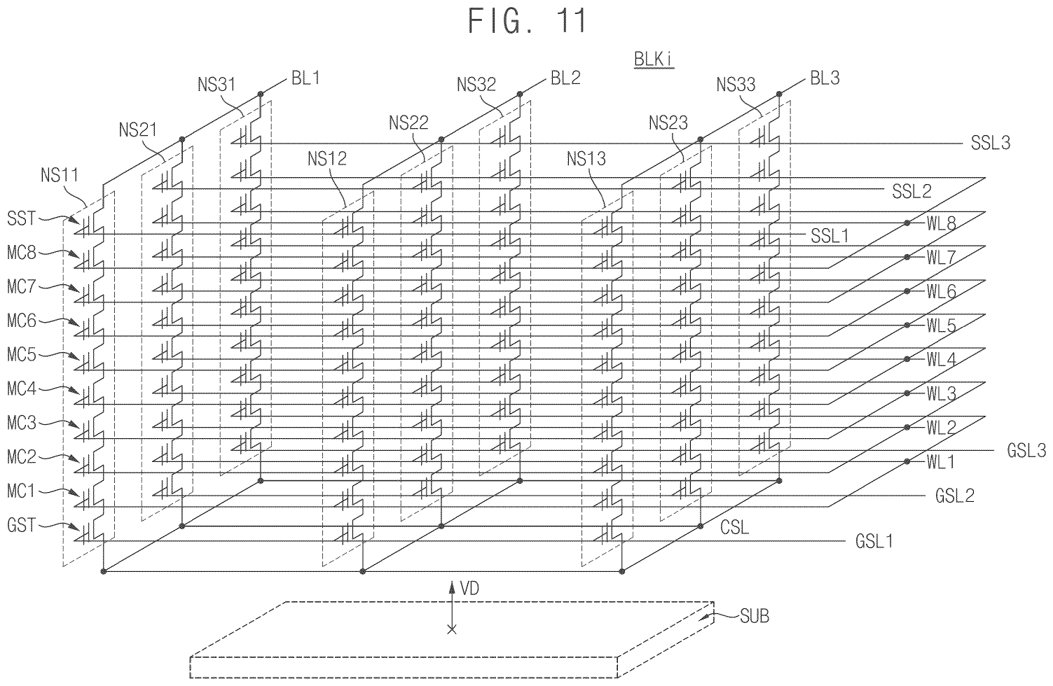

FIG. 9 schematically illustrates a structure of the nonvolatile memory device of FIG. 8 according to example embodiments.

Referring to FIG. 9, the nonvolatile memory device 100 may include a first semiconductor layer L1 and a second semiconductor layer L2, and the first semiconductor layer L1 may be stacked in a vertical direction VD with respect to the second semiconductor layer L2. The second semiconductor layer L2 may be under the first semiconductor layer L1 in the vertical direction VD, and accordingly, the second semiconductor layer L2 may be close to a substrate.

In example embodiments, the memory cell array 200 in FIG. 8 may be formed (or, provided) on the first semiconductor layer L1, and the peripheral circuit 210 in FIG. 8 may be formed (or, provided) on the second semiconductor layer L2. Accordingly, the nonvolatile memory device 100 may have a structure in which the memory cell array 200 is on the peripheral circuit 210, that is, a cell over periphery (COP) structure. The COP structure may effectively reduce an area in a horizontal direction and improve the degree of integration of the memory device 10.

In example embodiments, the second semiconductor layer L2 may include the substrate, and by forming transistors on the substrate and metal patterns for wiring transistors, the peripheral circuit 210 may be formed in the second semiconductor layer L2. After the peripheral circuit 210 is formed on the second semiconductor layer L2, the first semiconductor layer L1 including the memory cell array 200 may be formed, and the metal patterns for connecting the word-lines WL and the bit-lines BL of the memory cell array 200 to the peripheral circuit 210 formed in the second semiconductor layer L2 may be formed. For example, the word-lines WL may extend in a first horizontal direction HD1, and the bit-lines BL may extend in a second horizontal direction HD2.

As the number of stages of memory cells in the memory cell array 200 increases with the development of semiconductor processes, that is, as the number of stacked word-lines WL increases, an area of the memory cell array 200 may decrease, and accordingly, an area of the peripheral circuit 210 may also be reduced. According to an embodiment, to reduce an area of a region occupied by the page buffer circuit 410, the page buffer circuit 410 may have a structure in which the page buffer unit and the cache latch are separated from each other, and may connect sensing nodes included in each of the page buffer units commonly to a combined sensing node. This will be explained in detail with reference to FIG. 13.

FIG. 10 is a block diagram illustrating an example of the memory cell array in FIG. 8 according to example embodiments.

Referring to FIG. 10, the memory cell array 200 may include a plurality of memory blocks BLK1 to BLKz which extend along a plurality of directions HD1, HD2 and VD. In an embodiment, the memory blocks BLK1 to BLKz are selected by the address decoder 300 in FIG. 8. For example, the address decoder 300 may select a memory block corresponding to a block address among the memory blocks BLK1 to BLKz.

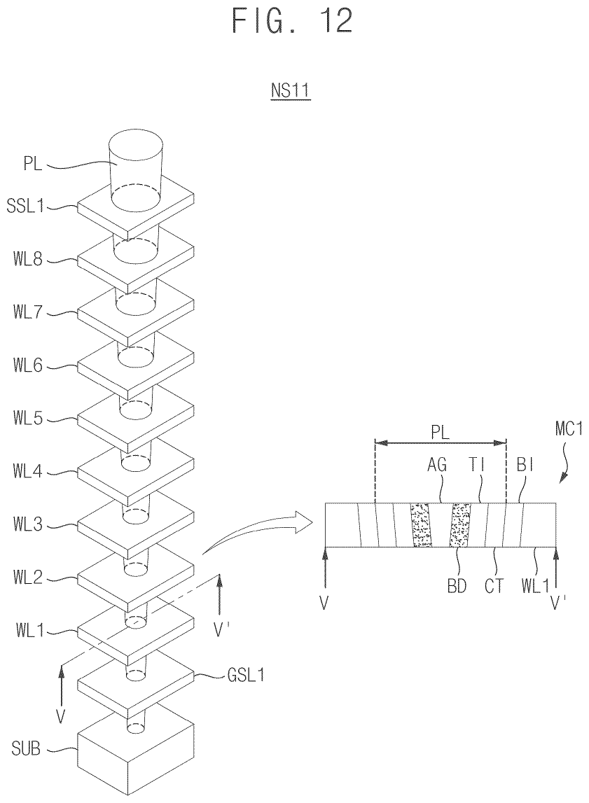

FIG. 11 is a circuit diagram illustrating one of the memory blocks of FIG. 10.

The memory block BLKi of FIG. 11 may be formed on a substrate SUB in a three-dimensional structure (or a vertical structure). For example, a plurality of memory cell strings included in the memory block BLKi may be formed in the vertical direction VD perpendicular to the substrate SUB.

Referring to FIG. 11, the memory block BLKi may include (memory) cell strings NS11, NS21, NS31, NS12, NS22, NS32, NS13, NS23 and NS33 (hereinafter, represented as NS11 to NS33) coupled between bit-lines BL1, BL2 and BL3 and a common source line CSL. Each of the cell strings NS11 to NS33 may include a string selection transistor SST, a plurality of memory cells MC1, MC2, MC3, MC4, MC5, MC6, MC7 and MC8 (hereinafter represented as MC1 to MC8), and a ground selection transistor GST. In FIG. 11, each of the cell strings NS11 to NS33 is illustrated to include eight memory cells MC1 to MC8. However, present disclosure are not limited thereto. In some example embodiments, each of the cell strings NS11 to NS33 may include any number of memory cells.

The string selection transistor SST may be connected to corresponding string selection lines SSL1, SSL2 and SSL3 (hereinafter, represented as SSL1 to SSL3). The plurality of memory cells MC1 to MC8 may be connected to corresponding word-lines WL1 to WL8, respectively. The ground selection transistor GST may be connected to corresponding ground selection lines GSL1, GSL2 and GSL3 (hereinafter, represented as GSL1 to GSL3). The string selection transistor SST may be connected to corresponding bit-lines BL1, BL2 and BL3, and the ground selection transistor GST may be connected to the common source line CSL.

Word-lines (e.g., WL1) having the same height may be commonly connected, and the ground selection lines GSL1 to GSL3 and the string selection lines SSL1 to SSL3 may be separated.

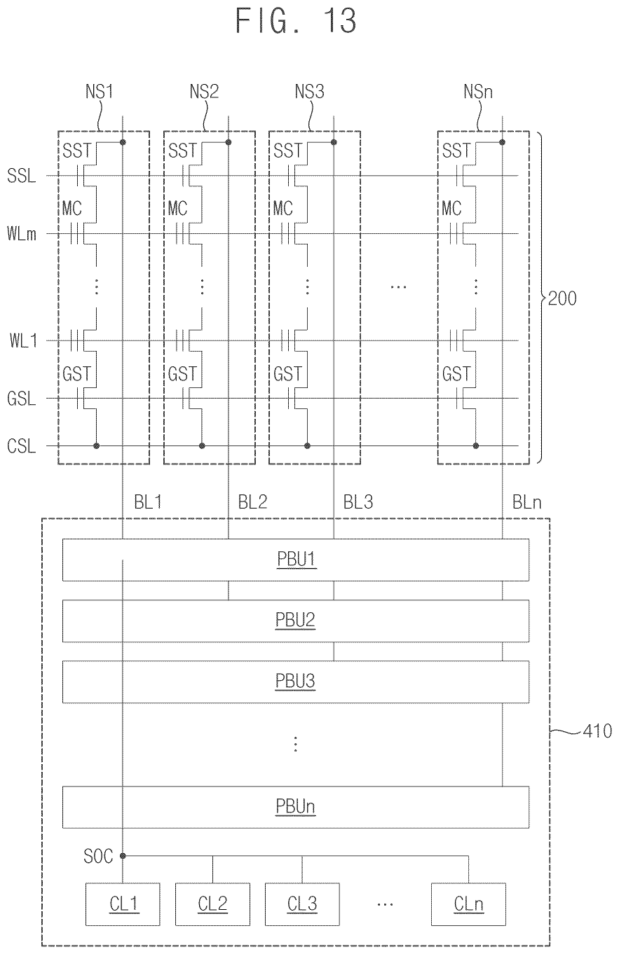

FIG. 12 illustrates an example of a structure of a cell string CS in the memory block of FIG. 11.

Referring to FIGS. 11 and 12, a pillar PL is provided on the substrate SUB such that the pillar PL extends in a direction perpendicular to the substrate SUB to make contact with the substrate SUB. Each of the ground selection line GSL, the word-lines WL1 to WL8, and the string selection lines SSL1 illustrated in FIG. 12 may be formed of a conductive material parallel with the substrate SUB, for example, a metallic material. The pillar PL may be in contact with the substrate SUB through the conductive materials forming the string selection lines SSL, the word-lines WL1 to WL8, and the ground selection line GSL1.

A sectional view taken along a line V-V′ is also illustrated in FIG. 12. In some example embodiments, a sectional view of a first memory cell MC1 corresponding to a first word-line WL1 is illustrated. The pillar PL may include a cylindrical body BD. An air gap AG may be defined in the interior of the body BD.

The body BD may include P-type silicon and may be an area where a channel will be formed. The pillar PL may further include a cylindrical tunnel insulating layer TI surrounding the body BD and a cylindrical charge trap layer CT surrounding the tunnel insulating layer TI. A blocking insulating layer BI may be provided between the first word-line WL1 and the pillar PL. The body BD, the tunnel insulating layer TI, the charge trap layer CT, the blocking insulating layer BI, and the first word-line WL1 may constitute or be included in a charge trap type transistor that is formed in a direction perpendicular to the substrate SUB or to an upper surface of the substrate SUB. A string selection transistor SST, a ground selection transistor GST, and other memory cells may have the same structure as the first memory cell MC1.

FIG. 13 is a schematic diagram of a connection of the memory cell array to the page buffer circuit in FIG. 8, according to example embodiments.

Referring to FIG. 13, the memory cell array 200 may include first through n-th NAND strings NS1, NS2, NS3, . . . , NSn (hereinafter, represented as NS1 through NSn), each of the first through n-th NAND strings NS1 through NSn may include a ground select transistor GST connected to the ground select line GSL, a plurality of memory cells MC respectively connected to the first through m-th word-lines WL1, . . . , WLm (hereinafter, represented as WL1 through WLm), and a string select transistor SST connected to the string select line SSL, and the ground select transistor GST, the plurality of memory cells MC, and the string select transistor SST may be connected to each other in series. In this case, m may be a positive integer.

The page buffer circuit 410 may include first through n-th page buffer units PB1, PB2, PB3, . . . , PBn (hereinafter, represented as PBU1 through PBUn). The first page buffer unit PB1 may be connected to the first NAND string NS1 via the first bit-line BL1, and the n-th page buffer unit PBUn may be connected to the n-th NAND string NSn via the n-th bit-line BLn. In this case, n may be a positive integer greater than 3. For example, n may be 8, and the page buffer circuit 410 may have a structure in which page buffer units of eight stages, or, the first through n-th page buffer units PBU1 through PBUn are in a line. For example, the first through n-th page buffer units PBU1 through PBUn may be in a row in an extension direction of the first through n-th bit-lines BL1 through BLn.

The page buffer circuit 410 may further include first through n-th cache latches CL1, CL2, CL3, . . . , CLn (hereinafter, represented as CL1 through CLn) respectively corresponding to the first through n-th page buffer units PBU1 through PBUn. For example, the page buffer circuit 410 may have a structure in which the cache latches of eight stages or the first through n-th cache latches CL1 through CLn in a line. For example, the first through n-th cache latches CL1 through CLn may be in a row in an extension direction of the first through n-th bit-lines BL1 through BLn.

The sensing nodes of each of the first through n-th page buffer units PBU1 through PBUn may be commonly connected to a combined sensing node SOC. In addition, the first through n-th cache latches CL1 through CLn may be commonly connected to the combined sensing node SOC. Accordingly, the first through n-th page buffer units PBU1 through PBUn may be connected to the first through n-th cache latches CL1 through CLn via the combined sensing node SOC.

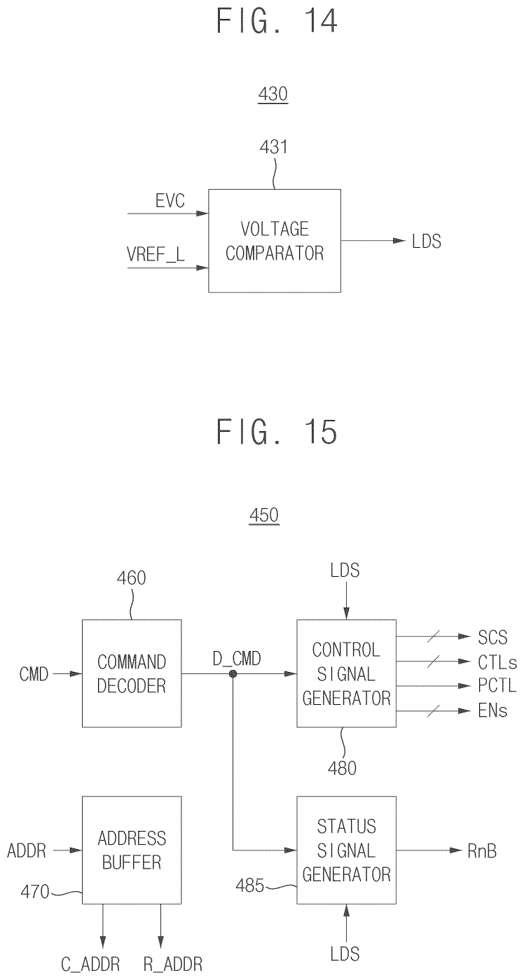

FIG. 14 is a block diagram illustrating an example of the voltage detector in the nonvolatile memory device of FIG. 8 according to example embodiments.

Referring to FIG. 14, the voltage detector 430 may include a voltage comparator 431.

The voltage comparator 431 may compare a voltage level (for example, a detected voltage level) of the external voltage EVC with at least one reference level VREF_L, may generate the level detection signal LDS indicating whether the voltage level of the external voltage EVC is equal to or greater than the at least one reference level VREF_L based on the comparison and provide the level detection signal LDS to the control circuit 450.

In example embodiments, the at least one reference level VREF_L may include a reference level and the level detection signal LDS may include one bit indicating whether the voltage level of the external voltage EVC is equal to or greater than the reference level.

In example embodiments, the at least one reference level VREF_L may include two or more reference levels and the level detection signal LDS may include a plurality of bits indicating whether the voltage level of the external voltage EVC is equal to or greater than each of the two or more reference levels.

FIG. 15 is a block diagram illustrating an example of the control circuit in the nonvolatile memory device of FIG. 8 according to example embodiments.

Referring to FIG. 15, the control circuit 450 may include a command decoder 460, an address buffer 470, a control signal generator 480 and a status signal generator 485.

The command decoder 460 may decode the command CMD and provide a decoded command D_CMD to the control signal generator 480 and the status signal generator 485.

The address buffer 470 may receive the address signal ADDR, provide the row address R_ADDR to the address decoder 300 and provide the column address C_ADDR to the data I/O circuit 420.

The control signal generator 480 may receive the decoded command D_CMD and the level detection signal LDS, may generate the control signals CTLs and the enable signals ENs based on an operation directed by the decoded command D_CMD and the level detection signal LDS and may provide the control signals CTLs and the enable signals ENs to the voltage generation circuit 500. The control signal generator 480 may generate the page buffer control signal PCTL based on an operation directed by the decoded command D_CMD, may provide the page buffer control signal PCTL to the page buffer circuit 410, may generate the switching control signals SCS and may provide the switching control signals SCS to the address decoder 300.

The status signal generator 485 may receive the decoded command D_CMD and the level detection signal LDS, may monitor an operation directed by the decoded command D_CMD and may transition the status signal RnB one of a ready state or a busy state based on whether the operation directed by the decoded command D_CMD is completed. The status signal generator 485 may adaptively adjust a period to maintain a busy state of the status signal RnB based on the level detection signal LDS in a read operation of the nonvolatile memory device 100.

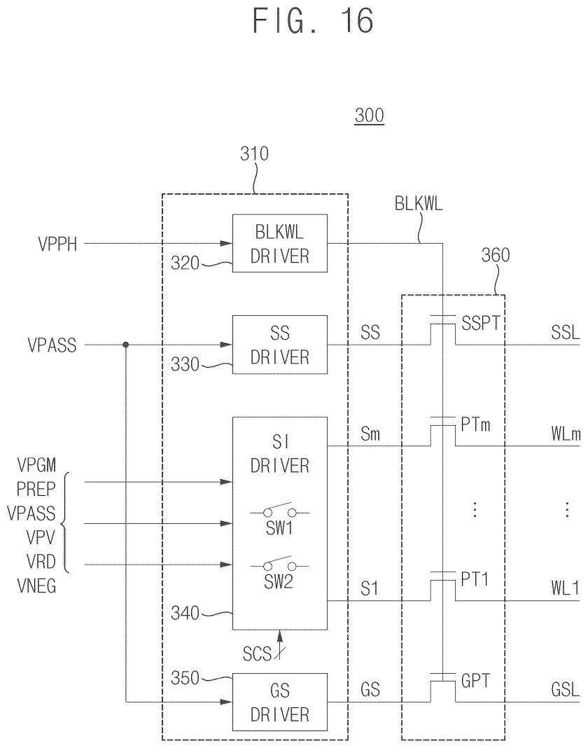

FIG. 16 is a block diagram illustrating an example of the address decoder in the nonvolatile memory device of FIG. 8 according to example embodiments.

Referring to FIG. 16, the address decoder 300 may include a driver circuit 310 and a pass switch circuit 360.

The driver circuit 310 may transfer voltages provided from the voltage generation circuit 500 to the memory cell array 200 in response to a block address. The driver circuit 310 to the memory cell array 200. The driver circuit 310 may include a block selection driver BWLWL DRIVER 320, a string selectin driver SS DRIVER 330, a driving line driver SI DRIVER 340 and a ground selection driver GS DRIVER 350.

The block selection driver 320 may supply a high voltage VPPH from the voltage generation circuit 500 to the pass transistor circuit 360 in response to the block address. The block selection driver 320 may supply the high voltage VPPH to a block word-line BLKWL coupled to gates of a plurality of pass transistors GPT, PT1˜PTm and SSPT in the pass transistor circuit 360. The block selection driver 320 may control the application of various voltages such as a pass voltage, a program voltage, a read voltage to the memory cell array 200.

The string selection driver 330 may supply voltage (for example, pass voltage VPASS) from the voltage generation circuit 500 to the string selection line SSL through the pass transistor SSPT as a string selection signal SS. During a program operation, the string selection driver 330 may supply the selection signal SS so as to turn on all string selection transistors in a selected memory block.

The driving line driver 340 may supply a program voltage VPGM, a pass voltage VPASS, a verification voltage VPV, a pre-pulse PREP, a read voltage VRD and a negative voltage VNEG from the voltage generation circuit 500 to the word-lines WL1˜WLm through driving lines S1˜Sm and the pass transistors PT1˜PTm.

The driving line driver 340 may include a first switch SW1 and a second switch SW2. The first switch SW1 may transfer the pass voltage VPASS, the pre-pulse PREP and the negative voltage VNEG to the unselected word-lines in response to the switching control signal SCS. The second switch SW2 may transfer at least a portion of the program voltage VPGM, the verification voltage VPV, the read voltage VRD and the negative voltage VNEG to the selected word-line in response to the switching control signal SCS.

The ground selection driver 350 may supply voltage (for example, pass voltage VPASS) from the voltage generation circuit 500 to the ground selection line GSL through the pass transistor GPT as a ground selection signal GS.

The pass transistors GPT, PT1˜PTm and SSPT are configured such that the ground selection line GSL, the word-lines WL1˜WLm and the string selection line SSL are electrically connected to corresponding driving lines, in response to activation of the high voltage VPPH on the block word-line BLKWL. In example embodiments, each of the pass transistors GPT, PT1˜PTm, SSPT CPT may include a high voltage transistor capable of enduring high-voltage.

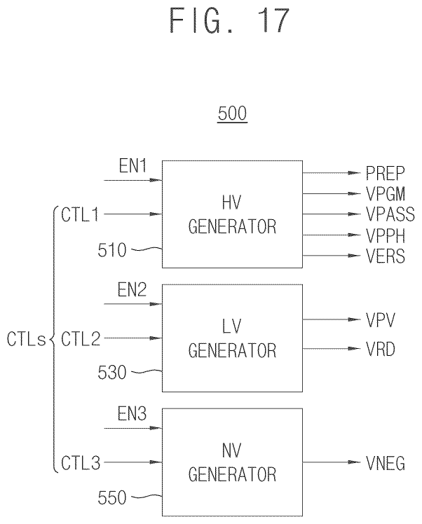

FIG. 17 is a block diagram illustrating an example of the voltage generator in the nonvolatile memory device of FIG. 8 according to example embodiments.

Referring to FIG. 17, the voltage generation circuit 500 may include a high voltage HV generator 510 and a low voltage LV generator 530. The voltage generation circuit 500 may further include a negative voltage NV generator 550.

The high voltage generator 510 may be referred to as a first voltage generator, the low voltage generator 530 may be referred to as a second voltage generator and the negative voltage generator 550 may be referred to as a third voltage generator.

The high voltage generator 510 may be enabled in response to a first enable signal EN and may generate the program voltage PGM, the pass voltage VPASS, the high voltage VPPH, the pre-pulse PREP and the erase voltage VERS according to operations directed by the command CMD, in response to a first control signal CTL1.

The program voltage PGM is applied to the selected word-line, the pre-pulse PREP and the pass voltage VPASS may be applied to the unselected word-lines, the erase voltage VERS may be applied to a channel of cell strings included in a selected memory block. The high voltage VPPH may be applied to each gate of pass transistors coupled to word-lines, a string selection line and a ground selection line. The first control signal CTL1 may include a plurality of bits which indicate the operations directed by the decoded command D_CMD.

The low voltage generator 530 may be enabled in response to a second enable signal EN2 and may generate the program verification voltage VPV and the read voltage VRD according to operations directed by the command CMD, in response to a second control signal CTL2. The program verification voltage VPV and the read voltage VRD may be applied to the selected word-line according to operation of the nonvolatile memory device 100. The second control signal CTL2 may include a plurality of bits which indicate the operations directed by the decode command D_CMD.

The negative voltage generator 550 may be enabled in response to a third enable signal EN3 and may generate a negative voltage VNEG which has a negative level according to operations directed by the command CMD, in response to a third control signal CTL3. The third control signal CTL3 may include a plurality of bits which indicate the operations directed by the decoded command D_CMD. The negative voltage VNEG may be applied to a selected word-line and unselected word-lines during a program recovery period and may be applied to the unselected word-lines during a bit-line set-up period.

The first enable signal EN1, the second enable signal EN2 and the third enable signal EN3 may be included in the enable signals ENs in FIG. 8.

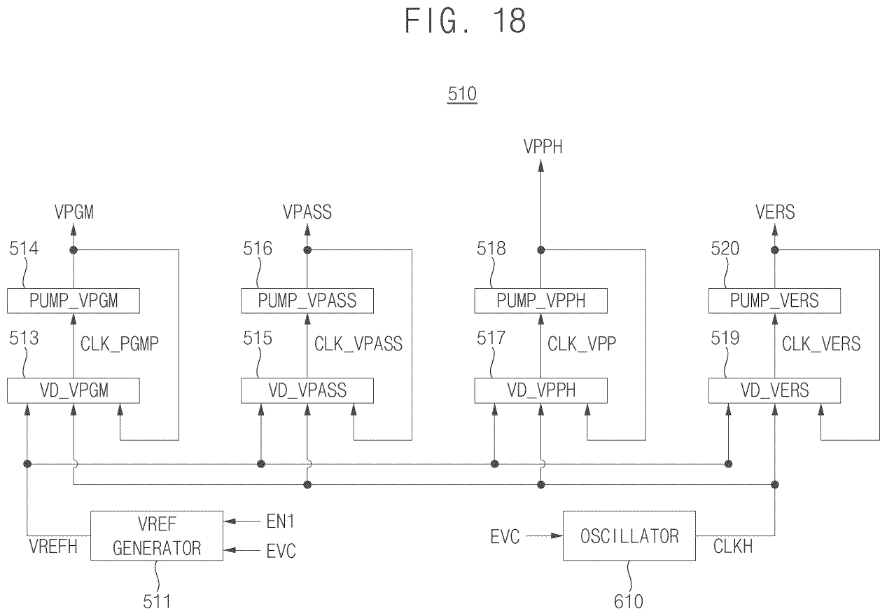

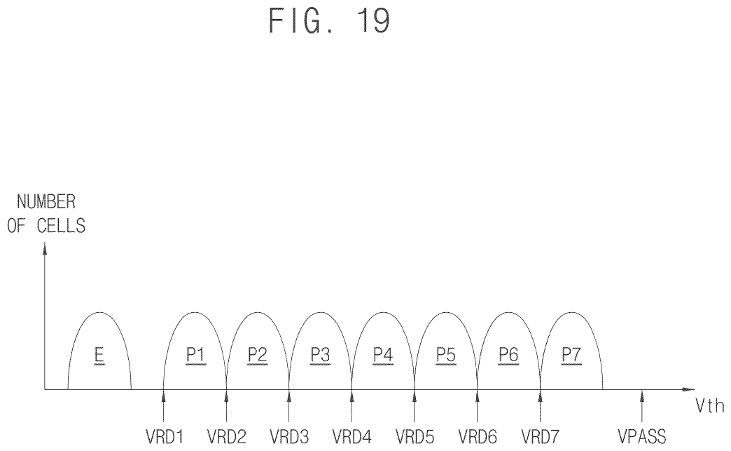

FIG. 18 is a block diagram illustrating an example of the high voltage generator in the voltage generation circuit of FIG. 17 according to example embodiments.

Referring to FIG. 18, the high voltage generator 510 may include a reference voltage generator VREF GENERATOR 511, an oscillator 610, a program voltage detector VD_VPGM 513, a program voltage pump PUMP_VPGM 514, a pass voltage detector VD_VPASS 515, a pass voltage pump PUMP_VPASS 516, a high voltage detector VD_VPPH 517, a high voltage pump PUMP_VPPH 518, an erase voltage detector VD_VERS 519, and an erase voltage pump PUMP_VERS 520.

The reference voltage generator 511 may generate a reference voltage VREFH based on the external voltage EVC. The oscillator 610 may generate a clock signal CLKH based on the external voltage EVC.

The program voltage detector 513 may receive the reference voltage VREFH and the clock signal CLKH, detect the program voltage VPGM and generate a program voltage clock CLK_VPGM. The program voltage pump 514 may generate the program voltage VPGM by operating a boosting circuit based on the program voltage clock CLK_VPGM.

The pass voltage detector 515 may receive the reference voltage VREFH and the clock signal CLKH, detect the pass voltage VPASS and generate a pass voltage clock CLK_VPASS. The pass voltage pump 516 may generate the pass voltage VPASS by operating a boosting circuit based on the pass voltage clock CLK_VPASS.

The high voltage detector 517 may receive the reference voltage VREFH and the clock signal CLKH, detect the high voltage VPPH and generate a high voltage clock CLK_VPPH. The high voltage pump 518 may generate the high voltage VPPH by operating a boosting circuit based on the high voltage clock CLK_VPPH.

The erase voltage detector 519 may receive the reference voltage VREFH and the clock signal CLKH, detect the erase voltage VERS and generate an erase voltage clock CLK_VERS. The erase voltage pump 520 may generate the erase voltage VERS by operating a boosting circuit based on the erase voltage clock CLK_VERS.

The control circuit 450 in FIG. 8 may enable the reference voltage generator 511 by applying the first enable signal EN1 to the reference voltage generator 511.

FIG. 19 is a graph showing a threshold voltage distributions of memory cells in FIG. 11.

In FIG. 19, a horizontal axis represents a threshold voltage Vth and the vertical axis represents the number of memory cells.

Below, to describe embodiments of the present disclosure easily, it is assumed that each of the memory cells of the nonvolatile memory device 100 is a triple level cell (TLC) configured to store 3-bit data. However, the present disclosure is not limited thereto. For example, each memory cell may be a single level cell (SLC) storing 1-bit data, or a multi-level cell (MLC), a triple level cell (TLC), a quad level cell (QLC) or a penta level cell (PLC) storing q-bit data (q being a natural number greater than 1).

Referring to FIGS. 11 and 19, each memory cell may be programmed to have one of an erase state “E” and first to seventh program states P1, P2, P3, P4, P5, P6 and P7. To read data programmed in the memory cells, the nonvolatile memory device 100 may use a plurality of read voltages VRD1, VRD2, VR3, VRD4, VRD5, VRD6 and VRD7 and a read pass voltage VPASS. For example, to read data programmed in memory cells connected with a selected word-line, the nonvolatile memory device 100 may sequentially apply the plurality read voltages VRD1, VRD2, VR3, VRD4, VRD5, VRD6 and VRD7 to the selected word-line and may apply the read pass voltages VPASS to the unselected word-lines. A voltage level of the read pass voltages VPASS may be greater than voltage levels of the read voltages VRD1, VRD2, VR3, VRD4, VRD5, VRD6 and VRD7.

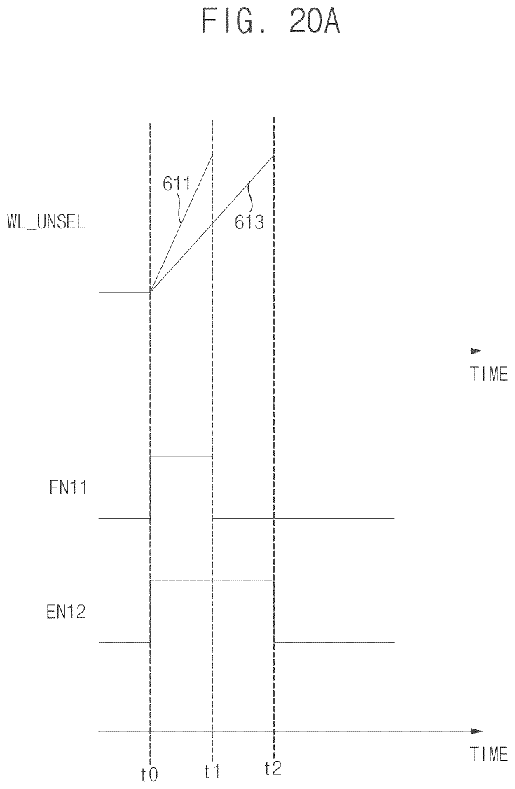

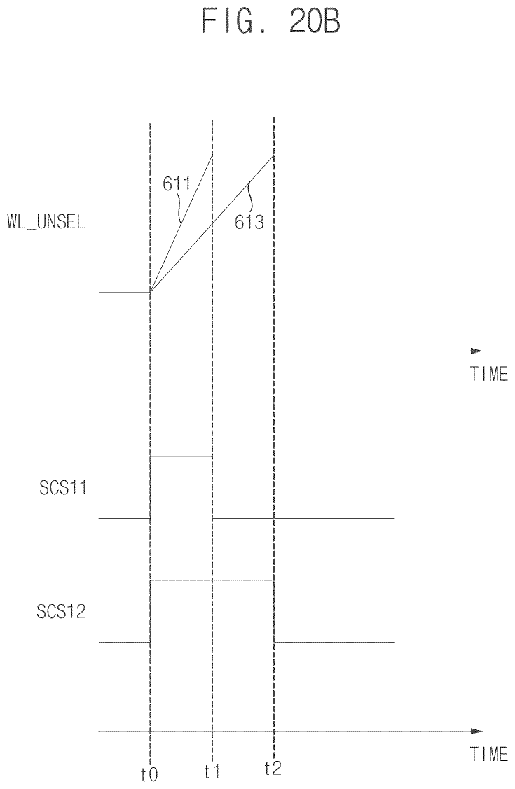

FIG. 20A is a timing diagram illustrating an example operation of the voltage generation circuit of FIG. 17 according to example embodiments.

In FIG. 20A, the selected word-line and the read voltage are omitted for convenience of explanation.

Referring to FIGS. 14, 17 and 20A, when the level detection signal LDS indicates that the voltage level of the external voltage EVC is equal to or greater than the at least one reference level VREF_L, the control circuit 450 enables the high voltage generator 510 during a first time interval t0˜t1 to increase voltages of the unselected word-lines WL_UNSEL to the read pass voltage VPASS as a reference numeral 611 indicates by applying a first enable signal EN11 to the high voltage generator 510 during the first time interval t0˜t1. When the level detection signal LDS indicates that the voltage level of the external voltage EVC is smaller than the at least one reference level VREF_L, the control circuit 450 enables the high voltage generator 510 during a second time interval t0˜t2 greater than the first time interval t0˜t1 to increase voltages of the unselected word-lines WL_UNSEL to the read pass voltage VPASS as a reference numeral 613 indicates by applying a second enable signal EN12 to the high voltage generator 510 during second time interval t0˜t2.

That is, the control circuit 450 may adaptively adjust a ramping period during which the read pass voltage VPASS ramps to a target level by adjusting activation interval of the enable signals EN11 and EN12 applied to the high voltage generator 510 based on the voltage level of the external voltage EVC.

FIG. 20B is a timing diagram illustrating an example operation of the address decoder of FIG. 16 according to example embodiments.

In FIG. 20B, the selected word-line and the read voltage are omitted for convenience of explanation.

Referring to FIGS. 14, 16 and 20B, when the level detection signal LDS indicates that the voltage level of the external voltage EVC is equal to or greater than the at least one reference level VREF_L, the control circuit 450 turns-on the first switch SW1 during a first time interval t0˜t1 by applying a first switching control signal SCS11 during the first time interval t0˜t1. Therefore, the read pass voltage VPASS is transferred to the unselected word-lines WL_UNSEL during the first time interval t0˜t1 as a reference numeral 611. When the level detection signal LDS indicates that the voltage level of the external voltage EVC is smaller than the at least one reference level VREF_L, the control circuit 450 turns-on the first switch SW1 during a second time interval t0˜t2 greater than the first time interval t0˜t1 by applying a second switching control signal SCS12 during the second time interval t0˜t2. Therefore, the read pass voltage VPASS is transferred to the unselected word-lines WL_UNSEL during the second time interval t0˜t2 as a reference numeral 613

That is, the control circuit 450 may adaptively adjust a ramping period during which the read pass voltage VPASS ramps to a target level by adjusting activation interval of the switching control signals SCS11 and SCS12 applied to the driving line driver 340 based on the voltage level of the external voltage EVC.

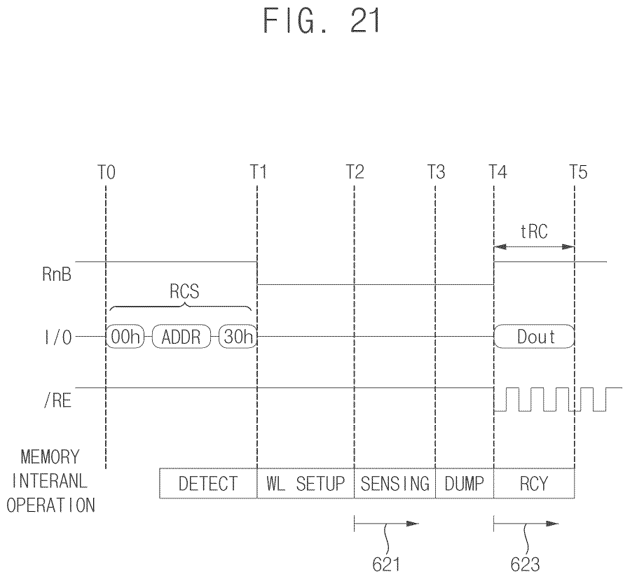

FIG. 21 is a timing diagram illustrating an example operation of the memory system of FIG. 6.

Referring to FIGS. 6 and 21, the memory controller 50 may fetch read data before word-line recovery of the nonvolatile memory device 100 is completed.

During a high-level (ready state) period of the status signal RnB between a time interval T0 to T1, the memory controller 50 may issue a read command (00h, ADDR, 30h) through I/O terminals I/O to the nonvolatile memory device 100. The read command may be provided as the read command sequence RCS. The nonvolatile memory device 100 may detect a voltage level of the external voltage EVC during ADDR and 30h are being received. When an input of the read command is completed, the nonvolatile memory device 100 may transition the status signal RnB to a low level (busy state). Alternatively, the nonvolatile memory device 100 may be responsive to a status read command received through the I/O terminals I/O to transmit the busy state to the memory controller 50.

The nonvolatile memory device 100 may generate a word-line voltage to be provided to a selected memory region in response to the read command, and the word-line voltage may be applied to the selected memory region. This operation may be a word-line setup period WL SETUP corresponding to a time interval T1 to T2 in FIG. 21. The control circuit 450 may adjust a ramping period during which the read pass voltage ramps to a target level based on the voltage level of the external voltage EVC and thus, an ending point T2 of the word-line setup period WL SETUP may be adjusted as a reference numeral 621 indicates.

Then, the nonvolatile memory device 100 may sense and latch cells of the selected memory region. This operation may be a sensing period corresponding to a time interval T2 to T3 in FIG. 21. The sensed data may be dumped to the data I/O circuit 420. This operation may be a dump period DUMP corresponding to a time interval T3 to T4 in FIG. 21.

An ending point T4 of the dump period DUMP may be adjusted as a reference numeral 623 indicates when the word-line setup period WL SETUP is adjusted.

The nonvolatile memory device 100 may perform a recovery operation at a point of time T4 when dumping of the sensing data to the data I/O circuit 420 is completed. Here, the recovery operation may be performed to discharge a bulk, word-lines, bit-lines, selection lines, a common source line, etc. associated with the selected memory cells. Also, the nonvolatile memory device 100 may set the status signal RnB to a high level (ready state) at a point of time T4 when dumping of the sensed data to the data I/O circuit 420 is completed. To output data of the nonvolatile memory device 100 to the external memory controller 50 may be possible from a point of time when the status signal RnB transitions to a high level. If the memory controller 50 provides a read enable signal/RE to the nonvolatile memory device 100 in response to a low-to-high transition of the status signal RnB, the nonvolatile memory device 100 may output the dumped data.

Here, it is beneficial to define a time when the sensed data is output during execution of the core recovery operation. Although the status signal RnB is set to a high level, an external command should not be provided to the nonvolatile memory device 100 during a time interval T4 to T5 when the recovery operation of the nonvolatile memory device 100 is performed. In this case, although a command is provided from the memory controller 50 to the nonvolatile memory device 100, an abnormal operation may be generated since the recovery operation is not completed. Thus, although a data output is ended, a command input may be prohibited during a time section tRC between a time point when the status signal RnB is set to a high level and a time point when the recovery operation is completed. Hereinafter, a time interval tRC may be referred to as a command wait time. At an access operation of the nonvolatile memory device 100, the memory controller 50 may issue a next command for a read, program, and erase operation after the command wait time tRC elapses.

FIG. 22 is a timing diagram schematically illustrating an example of a read operation of the nonvolatile memory device of FIG. 8 according to example embodiments.

Referring to FIGS. 8 and 22, the nonvolatile memory device 100 may sequentially perform a word-line setup operation WLS, a sensing operation SENSING, a dump operation DUMP, and a word-line recovery operation RCY in response to a read command sequence.

When the read command sequence is received during a high-level interval of the status (or, a ready/busy) signal RnB, the nonvolatile memory device 100 may set the status signal RnB to a low level and start an overall procedure for sensing selected memory cells.

At t0, the nonvolatile memory device 100 may perform the word-line setup operation. A high level of a string selection signal may be applied to a string selection line SSL of a selected memory block in the nonvolatile memory device 100, and the read pass voltage VPASS may be applied to unselected word-lines WL_UNSEL.

At t21, the nonvolatile memory device 100 may sense the selected memory cells. To sense the selected memory cells, a read voltage VRD may be applied to a selected word-line WL_SEL. Although not shown, bit-lines of memory cells may be pre-charged with a specific level for a sensing operation. Under this condition, in response to a sensing enable signal S_EN from the control circuit 450, the page buffer circuit 410 may sense bit-lines or sensing nodes supplied with bit-line precharge voltages. That is, the page buffer circuit 410 may store sensed data at a latch therein according to levels of the sensing nodes.

At t22, the control circuit 450 may provide a dump signal DMP to the page buffer circuit 410. In response to the dump signal DMP, the page buffer circuit 410 may output sensed data of the latch to the data I/O circuit 420. The sensed data output from the page buffer circuit 410 may be stored at a latch unit of the data I/O circuit 420. This dumping operation may be performed until t23.

At t23, the control circuit 450 may control the memory cell array 200, the address decoder 300, the page buffer circuit 410, the voltage generation circuit 500, etc. to discharge all voltages or currents provided for a read operation. That is, a recovery operation may be performed at t23 to recover a bias state of the memory cell array 200 to a state before the read operation. In addition, the control circuit 450 may set the status signal RnB to a high level at t23 when the dumping operation is completed. Alternatively, or in addition, if a status read command is received within such an interval, the control circuit 450 may output a ready state. A read enable signal/RE of read data stored in the data I/O circuit 420 may be activated at a point of time when the status signal RnB has a low-to-high transition.

During a command wait time tRC when the status signal RnB has a high level, the nonvolatile memory device 100 may perform the recovery operation. For example, at the recovery operation, a power supply voltage of the string selection line SSL may be discharged to a ground voltage (VSS, e.g., 0V) from a power supply voltage Vcc, and word-line voltage applied to the selected word-line WL_SEL may be discharged to a level of an off voltage VOFF. The word-line voltage applied to the unselected word-lines WL_UNSEL may be recovered to a level of the off voltage VOFF

The command wait time tRC may be decided in consideration of starting point and ending point of time of the recovery operation. During the command wait time tRC, as described above, a command input may be prohibited after the status signal RnB transitions to a high level.

Discharging the selected word-line WL_SEL and the unselected word-lines WL_UNSEL may be maintained unit t25.

Voltage waveforms of lines WL, SSL, and BL at the recovery operation (e.g., at a time section t23 to t24) are not limited to the examples shown in FIG. 22.

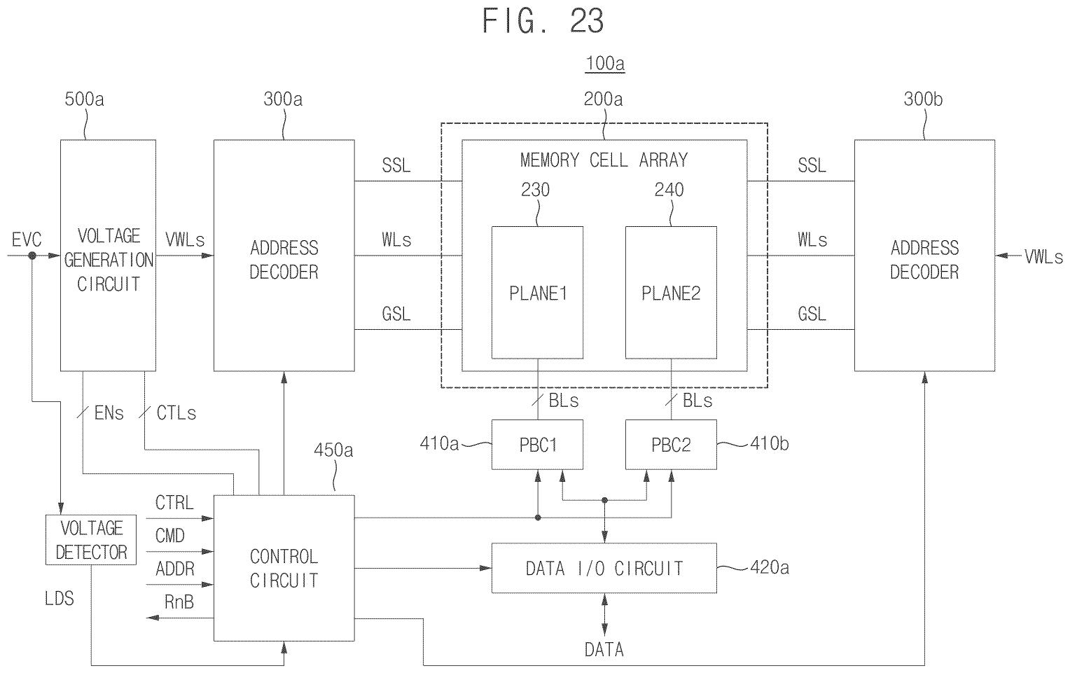

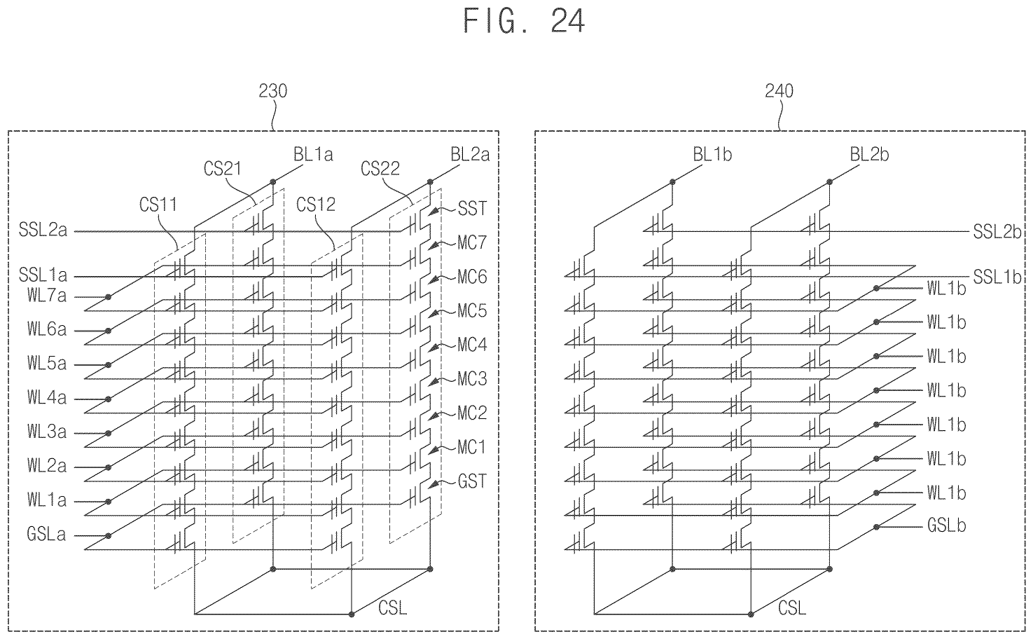

FIG. 23 is a block diagram illustrating a nonvolatile memory device according to example embodiments.

A nonvolatile memory device 100a may have multi-plane configuration. Although, the nonvolatile memory device 100a of FIG. 23 is illustrated as including two planes such as a first plane 230 and a second plane 240, the nonvolatile memory device 100a is not limited thereto, and may, for example, include a four plane configuration or a six plane configuration, etc.

The nonvolatile memory device 100a may include a memory cell array 200a, a first address decoder 300a, a second address decoder 300b, a first page buffer circuit 410a, a second page buffer circuit 410b, a data I/O circuit 420a, a control circuit 450a, a voltage generation circuit 500a and a voltage detector 430a.

The memory cell array 200a may include a first plane 230 and a second plane 240, and each of the first plane 230 and the second plane 240 may include a plurality of memory blocks as illustrated in FIG. 10.

Each memory block of each of the first plane 230 and the second plane 240 may be coupled to respective one of the first address decoder 300a and the second address decoder 300b through a string selection line SSL, a plurality of word-lines WLs, and a ground selection line GSL. The memory blocks in the first plane 230 may be coupled to the first page buffer circuit 410a through a plurality of bit-lines BLs and the memory blocks in the second plane 240 may be coupled to the second page buffer circuit 410b through a plurality of bit-lines BLs.

The first page buffer circuit 410a and the second page buffer circuit 410b may be coupled to the data I/O circuit 420a. The control circuit 450a may control the first address decoder 300a, the second address decoder 300b, the first page buffer circuit 410a, the second page buffer circuit 410b, the data I/O circuit 420a and the voltage generation circuit 500a based on the command CMD and the address ADDR from the memory controller 50. The control circuit 450a may output a status signal RnB.

The voltage generation circuit 500a may generate word-line voltages VWLs based on the external voltage EVC and may provide the word-line voltages VWLs to the memory cell array 200a through the first address decoder 300a and the second address decoder 300b.

The voltage detector 430a may compare a voltage level of the external voltage EVC with at least one reference level and may provide the control circuit 450 with a level detection signal LDS indicating whether the voltage level of the external voltage EVC is equal to or greater than the at least one reference level, in a read operation of the nonvolatile memory device 100a.

The control circuit 450a, in response to the read command sequence, may control a read operation by setting up each of a plurality of word-lines coupled to the plurality of memory cells to a respective target level during a word-line set-up period while adaptively adjusting a ramping period during which a read pass voltage ramps to a target level based on the detected voltage level, performing a sensing operation on target memory cells by applying a read voltage to a selected word-line coupled to the target memory cells, among the plurality of word-lines while applying the read pass voltage to unselected word-lines among the plurality of word-lines during a sensing period and outputting a sensed data obtained by the sensing operation.

Each of the first address decoder 300a and the second address decoder 300b may employ the address decoder 300 of FIG. 16.

Therefore, each of the first address decoder 300a and the second address decoder 300b in the nonvolatile memory device 100a may provide voltages covering wide ranges corresponding to changes of word-line loading based on plane independent read (PIR) scheme and plane independent core (PIC) scheme.

FIG. 24 illustrates a first plane and a second plane of the nonvolatile memory device of FIG. 23 according to example embodiments.

Referring to FIGS. 23 and 24, the memory cell array 200a may include the first plane 230 and the second plane 240. A plurality of memory blocks may be included in the first and second planes 230 and 240. A plurality of cell strings are included in each of the memory blocks. For example, a plurality of cell strings CS11, CS12, CS21, and CS22 are included in one of the memory blocks included in the first plane 230. Each of the planes 230 and 240 may include a plurality of memory blocks, and one of the memory blocks may include a plurality of string selection lines SSL1a and SSL2a to select at least one of the cell strings CS11, CS12, CS21, and CS22. For example, when a selection voltage is applied to the first string selection line SSL1a of the first plane 230, the first and second cell strings CS11 and CS12 may be selected. Similarly, when a selection voltage is applied to the second string selection line SSL2a of the first plane 230, the third and fourth cell strings CS21 and CS22 may be selected.

In example embodiments, the first and second planes 230 and 240 may have substantially the same or the same physical structure. For example, similar to the first plane 230, the second plane 240 may include a plurality of memory blocks and a plurality of cell strings disposed on a single plane. Similarly, the second plane 240 may include a plurality of string selection lines SSL1b and SSL2b configured to select at least one of multiple cell strings.

The first and second planes 230 and 240 do not share a word-line, a bit-line, a string selection line, a ground select line, and a common source line. Some example embodiments have been described where each plane is connected to two bit-lines and seven word-lines. However, each plane may be connected to three or more bit-lines and seven or more or less word-lines. For example, first plane 230 is connected to bit-lines BL1a and BL2a, word-lines WL1a˜WL7a, and ground selection line GSLa, whereas second plane 240 is connected to bit-lines BL1b and BL2b, word-lines WL1b˜WL7b, and ground selection line GSLb.

Each of the cell strings CS11, CS12, CS21, and CS22 includes at least one string selection transistor, memory cells, and at least one ground selection transistor. For example, a single ground selection transistor GST, a plurality of memory cells MC1, MC2, MC3, MC4, MC5, MC6 and MC7 (hereinafter, represented as MC1 to MC7), and a single string selection transistor SST are sequentially formed at the single cell string CS22 to be perpendicular to a substrate. The other cell strings also have the same structure as the cell string CS22.

In example embodiments, a string selection line connected to each of the planes 230 and 240 is exclusively connected to only one corresponding plane. For example, each of the string selection lines SSL1a and SSL2a is connected to only the first plane 230. Similarly, each of the string selection lines SSL1b and SSL2b is connected to only the second plane 240. Thus, a single string selection line may select only cell strings include in a single plane. In addition, each string selection line may be independently controlled to independently select cell strings in each plane.

For example, a selection voltage may be independently applied to the first string selection line SSL1a to independently select the cell strings CS11 and CS12. When the selection voltage is applied to the first string selection line SSL1a, the selection voltage turns on a string selection transistor of the corresponding cell strings CS11 and CS12. When the string selection transistor is turned on, memory cells of the cell strings CS11 and CS12 and a bit-line are electrically connected to each other.

Meanwhile, when an unselect voltage is applied to the first string selection line SSL1a, the string selection transistor of the cell strings CS11 and CS12 may be turned off and the cell strings CS11 and CS12 may be unselected. Thus, the memory cells of the cell strings CS11 and CS12 are electrically insulated from a bit-line.

According to the above-described configuration, string selection lines separated in each plane are provided. The separated string selection line structure may minimize an effect caused by a defect that occurs at some of the string selection lines. The string selection lines separated in each plane are advantageous in independently selecting a cell string in each plane. That is, cell strings included in the first plane 230 may be selected fully independently of cell strings included in the second plane 240. The independent selection structure allows the nonvolatile memory device 100a to be easily controlled.

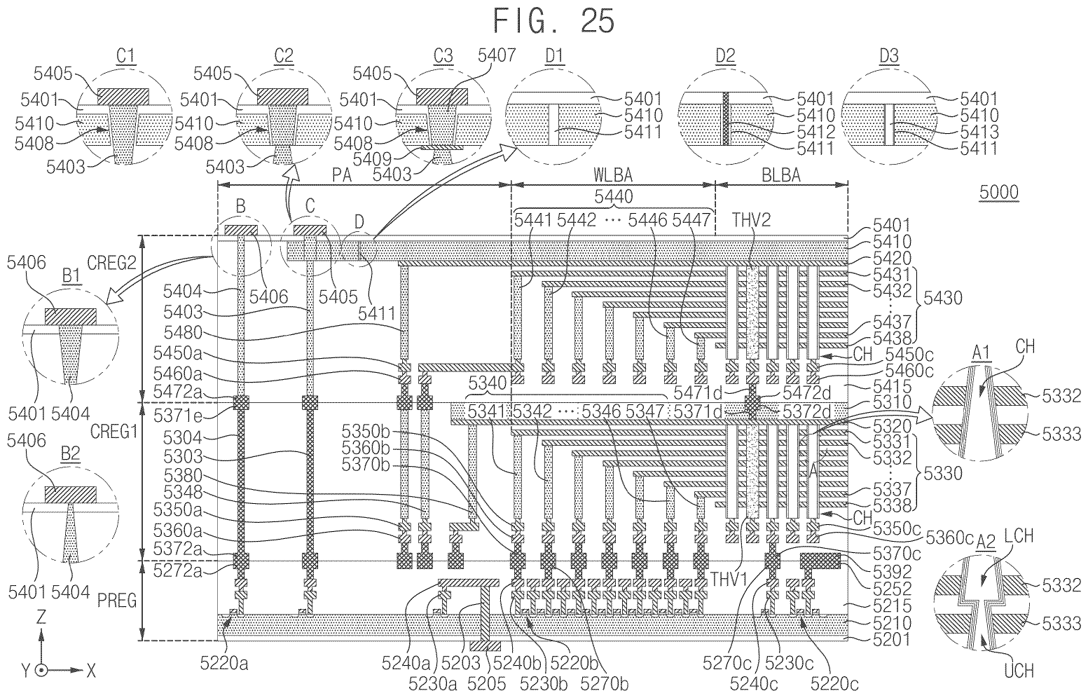

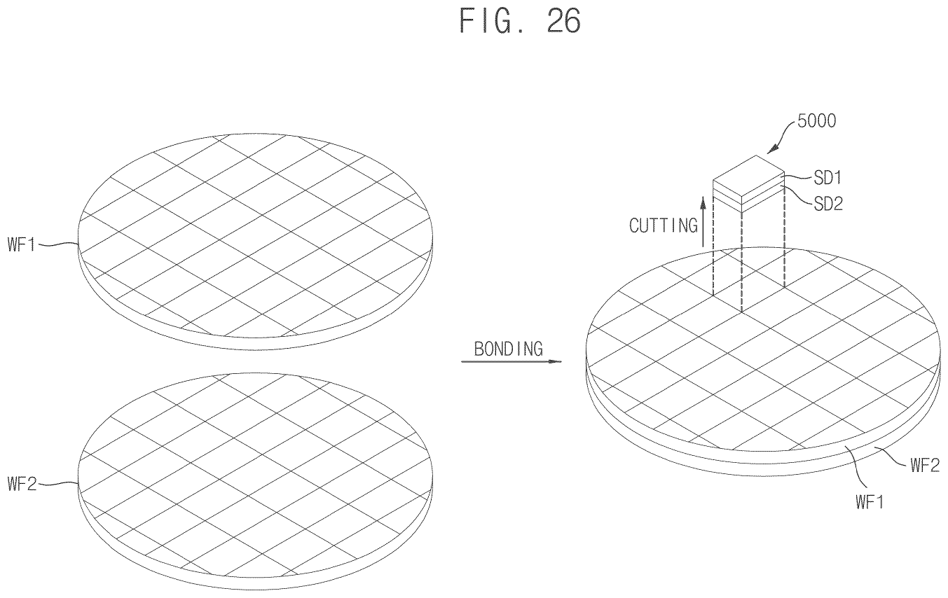

FIG. 25 is a cross-sectional view of a nonvolatile memory device according to some example embodiments.

Referring to FIG. 25, a nonvolatile memory device (or a memory device) 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 5000 may include the at least one upper chip including the cell region. For example, as illustrated in FIG. 25, the memory device 5000 may include two upper chips. However, the number of the upper chips is not limited thereto. In the case in which the memory device 5000 includes the two upper chips, a first upper chip including a first cell region CREG1, a second upper chip including a second cell region CREG2 and the lower chip including the peripheral circuit region PREG may be manufactured separately, and then, the first upper chip, the second upper chip and the lower chip may be connected to each other by the bonding method to manufacture the memory device 5000. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 25. However, example embodiments are not limited thereto. In some example embodiments, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a word-line bonding region WLBA, and a bit-line bonding region BLBA.

The peripheral circuit region PREG may include a first substrate 5210 and a plurality of circuit elements 5220a, 5220b and 5220c formed on the first substrate 5210. An interlayer insulating layer 5215 including one or more insulating layers may be provided on the plurality of circuit elements 5220a, 5220b and 5220c, and a plurality of metal lines electrically connected to the plurality of circuit elements 5220a, 5220b and 5220c may be provided in the interlayer insulating layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. For example, the first metal lines 5230a, 5230b and 5230c may be formed of tungsten having a relatively high electrical resistivity, and the second metal lines 5240a, 5240b and 5240c may be formed of copper having a relatively low electrical resistivity.

The first metal lines 5230a, 5230b and 5230c and the second metal lines 5240a, 5240b and 5240c are illustrated and described in the present embodiments. However, example embodiments are not limited thereto. In some example embodiments, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulating layer 5215 may be disposed on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of word-lines 5330 (5331 to 5338) may be stacked on the second substrate 5310 in a direction (here, the Z-axis direction) perpendicular to a top surface of the second substrate 5310. String selection lines and a ground selection line may be disposed on and under the word-lines 5330, and the plurality of word-lines 5330 may be disposed between the string selection lines and the ground selection line.

Likewise, the second cell region CREG2 may include a third substrate 5410 and a common source line 5420, and a plurality of word-lines 5430 (5431 to 5438) may be stacked on the third substrate 5410 in a direction (here, the Z-axis direction) perpendicular to a top surface of the third substrate 5410.

Each of the second substrate 5310 and the third substrate 5410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In some example embodiments, as illustrated in a region ‘A1’, the channel structure CH may be provided in the bit-line bonding region BLBA and may extend in the direction perpendicular to the top surface of the second substrate 5310 to penetrate the word-lines 5330, the string selection lines, and the ground selection line. The channel structure CH may include a data storage layer, a channel layer, and a filling insulation layer. The channel layer may be electrically connected to a first metal line 5350c and a second metal line 5360c in the bit-line bonding region BLBA. For example, the second metal line 5360c may be a bit-line and may be connected to the channel structure CH through the first metal line 5350c. The bit-line 5360c may extend in a first direction (e.g., a Y-axis direction) parallel to the top surface of the second substrate 5310.

In some example embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 5310 to penetrate the common source line 5320 and lower word-lines 5331 and 5332. The lower channel LCH may include a data storage layer, a channel layer, and a filling insulation layer and may be connected to the upper channel UCH. The upper channel UCH may penetrate upper word-lines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform or uniform width. The memory device 5000 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word-line located near to a boundary between the lower channel LCH and the upper channel UCH may be a dummy word-line. For example, the word-lines 5332 and 5333 adjacent to the boundary between the lower channel LCH and the upper channel UCH may be the dummy word-lines. In this case, data may not be stored in memory cells connected to the dummy word-line. Alternatively, the number of pages corresponding to the memory cells connected to the dummy word-line may be less than the number of pages corresponding to the memory cells connected to a general word-line. A level of a voltage applied to the dummy word-line may be different from a level of a voltage applied to the general word-line, and thus it is possible to reduce an influence of a non-uniform channel width between the lower and upper channels LCH and UCH on an operation of the memory device.

Meanwhile, the number of the lower word-lines 5331 and 5332 penetrated by the lower channel LCH is less than the number of the upper word-lines 5333 to 5338 penetrated by the upper channel UCH in the region ‘A2’. However, example embodiments are not limited thereto. In some example embodiments, the number of the lower word-lines penetrated by the lower channel LCH may be equal to or more than the number of the upper word-lines penetrated by the upper channel UCH. In addition, structural features and connection relation of the channel structure CH disposed in the second cell region CREG2 may be substantially the same or the same as those of the channel structure CH disposed in the first cell region CREG1.

In the bit-line bonding region BLBA, a first through-electrode THV1 may be provided in the first cell region CREG1, and a second through-electrode THV2 may be provided in the second cell region CREG2. As illustrated in FIG. 25, the first through-electrode THV1 may penetrate the common source line 5320 and the plurality of word-lines 5330. In some example embodiments, the first through-electrode THV1 may further penetrate the second substrate 5310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some example embodiments, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. The second through-electrode THV2 may be electrically connected to a third metal line 5450c and a fourth metal line 5460c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by the bonding method.

In addition, in the bit-line bonding region BLBA, an upper metal pattern 5252 may be formed in an uppermost metal layer of the peripheral circuit region PERI, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by the bonding method. In the bit-line bonding region BLBA, the bit-line 5360c may be electrically connected to a page buffer included in the peripheral circuit region PERI. For example, some of the circuit elements 5220c of the peripheral circuit region PREG may constitute the page buffer, and the bit-line 5360c may be electrically connected to the circuit elements 5220c constituting the page buffer through an upper bonding metal pattern 5370c of the first cell region CREG1 and an upper bonding metal pattern 5270c of the peripheral circuit region PERI.

Referring continuously to FIG. 25, in the word-line bonding region WLBA, the word-lines 5330 of the first cell region CREG1 may extend in a second direction (e.g., an X-axis direction) parallel to the top surface of the second substrate 5310 and may be connected to a plurality of cell contact plugs 5340 (5341 to 5347). First metal lines 5350b and second metal lines 5360b may be sequentially connected onto the cell contact plugs 5340 connected to the word-lines 5330. In the word-line bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PERI.

The cell contact plugs 5340 may be electrically connected to a row decoder included in the peripheral circuit region PERI. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PERI. In some example embodiments, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

Likewise, in the word-line bonding region WLBA, the word-lines 5430 of the second cell region CREG2 may extend in the second direction (e.g., the X-axis direction) parallel to the top surface of the third substrate 5410 and may be connected to a plurality of cell contact plugs 5440 (5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the word-line bonding region WLBA, the upper bonding metal patterns 5370b may be formed in the first cell region CREG1, and the upper bonding metal patterns 5270b may be formed in the peripheral circuit region PERI. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of aluminum, copper, or tungsten.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. Likewise, an upper metal pattern 5372a may be formed in an upper portion of the first cell region CREG1, and an upper metal pattern 5272a may be formed in an upper portion of the peripheral circuit region PERI. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output pads 5205, 5405 and 5406 may be disposed in the external pad bonding region PA. Referring to FIG. 25, a lower insulating layer 5201 may cover a bottom surface of the first substrate 5210, and a first input/output pad 5205 may be formed on the lower insulating layer 5201. The first input/output pad 5205 may be connected to at least one of a plurality of the circuit elements 5220a disposed in the peripheral circuit region PREG through a first input/output contact plug 5203 and may be separated from the first substrate 5210 by the lower insulating layer 5201. In addition, a side insulating layer may be disposed between the first input/output contact plug 5203 and the first substrate 5210 to electrically isolate the first input/output contact plug 5203 from the first substrate 5210.

An upper insulating layer 5401 covering a top surface of the third substrate 5410 may be formed on the third substrate 5410. A second input/output pad 5405 and/or a third input/output pad 5406 may be disposed on the upper insulating layer 5401. The second input/output pad 5405 may be connected to at least one of the plurality of circuit elements 5220a disposed in the peripheral circuit region PREG through second input/output contact plugs 5403 and 5303, and the third input/output pad 5406 may be connected to at least one of the plurality of circuit elements 5220a disposed in the peripheral circuit region PREG through third input/output contact plugs 5404 and 5304.

In some example embodiments, the third substrate 5410 may not be disposed in a region in which the input/output contact plug is disposed. For example, as illustrated in a region ‘B’, the third input/output contact plug 5404 may be separated from the third substrate 5410 in a direction parallel to the top surface of the third substrate 5410 and may penetrate an interlayer insulating layer 5415 of the second cell region CREG2 so as to be connected to the third input/output pad 5406. In this case, the third input/output contact plug 5404 may be formed by at least one of various processes.

In some example embodiments, as illustrated in a region ‘B1’, the third input/output contact plug 5404 may extend in a third direction (e.g., the Z-axis direction), and a diameter of the third input/output contact plug 5404 may become progressively greater toward the upper insulating layer 5401. In other words, a diameter of the channel structure CH described in the region ‘A1’ may become progressively less toward the upper insulating layer 5401, but the diameter of the third input/output contact plug 5404 may become progressively greater toward the upper insulating layer 5401. For example, the third input/output contact plug 5404 may be formed after the second cell region CREG2 and the first cell region CREG1 are bonded to each other by the bonding method.

In some example embodiments, as illustrated in a region ‘B2’, the third input/output contact plug 5404 may extend in the third direction (e.g., the Z-axis direction), and a diameter of the third input/output contact plug 5404 may become progressively less toward the upper insulating layer 5401. In other words, like the channel structure CH, the diameter of the third input/output contact plug 5404 may become progressively less toward the upper insulating layer 5401. For example, the third input/output contact plug 5404 may be formed together with the cell contact plugs 5440 before the second cell region CREG2 and the first cell region CREG1 are bonded to each other.

In some example embodiments, the input/output contact plug may overlap with the third substrate 5410. For example, as illustrated in a region ‘C’, the second input/output contact plug 5403 may penetrate the interlayer insulating layer 5415 of the second cell region CREG2 in the third direction (e.g., the Z-axis direction) and may be electrically connected to the second input/output pad 5405 through the third substrate 5410. In this case, a connection structure of the second input/output contact plug 5403 and the second input/output pad 5405 may be realized by various methods.

In some example embodiments, as illustrated in a region ‘C1’, an opening 5408 may be formed to penetrate the third substrate 5410, and the second input/output contact plug 5403 may be connected directly to the second input/output pad 5405 through the opening 5408 formed in the third substrate 5410. In this case, as illustrated in the region ‘C1’, a diameter of the second input/output contact plug 5403 may become progressively greater toward the second input/output pad 5405. However, example embodiments are not limited thereto, and in some example embodiments, the diameter of the second input/output contact plug 5403 may become progressively less toward the second input/output pad 5405.

In some example embodiments, as illustrated in a region ‘C2’, the opening 5408 penetrating the third substrate 5410 may be formed, and a contact 5407 may be formed in the opening 5408. An end of the contact 5407 may be connected to the second input/output pad 5405, and another end of the contact 5407 may be connected to the second input/output contact plug 5403. Thus, the second input/output contact plug 5403 may be electrically connected to the second input/output pad 5405 through the contact 5407 in the opening 5408. In this case, as illustrated in the region ‘C2’, a diameter of the contact 5407 may become progressively greater toward the second input/output pad 5405, and a diameter of the second input/output contact plug 5403 may become progressively less toward the second input/output pad 5405. For example, the second input/output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In some example embodiments illustrated in a region ‘C3’, a stopper 5409 may further be formed on a bottom end of the opening 5408 of the third substrate 5410, as compared with the embodiments of the region ‘C2’. The stopper 5409 may be a metal line formed in the same layer as the common source line 5420. Alternatively, the stopper 5409 may be a metal line formed in the same layer as at least one of the word-lines 5430. The second input/output contact plug 5403 may be electrically connected to the second input/output pad 5405 through the contact 5407 and the stopper 5409.

Like the second and third input/output contact plugs 5403 and 5404 of the second cell region CREG2, a diameter of each of the second and third input/output contact plugs 5303 and 5304 of the first cell region CREG1 may become progressively less toward the lower metal pattern 5371e or may become progressively greater toward the lower metal pattern 5371e.

Meanwhile, in some example embodiments, a slit 5411 may be formed in the third substrate 5410. For example, the slit 5411 may be formed at a certain position of the external pad bonding region PA. For example, as illustrated in a region ‘D’, the slit 5411 may be located between the second input/output pad 5405 and the cell contact plugs 5440 when viewed in a plan view. Alternatively, the second input/output pad 5405 may be located between the slit 5411 and the cell contact plugs 5440 when viewed in a plan view.

In some example embodiments, as illustrated in a region ‘D1’, the slit 5411 may be formed to penetrate the third substrate 5410. For example, the slit 5411 may be used to prevent or reduce the third substrate 5410 from being finely cracked when the opening 5408 is formed. However, example embodiments are not limited thereto, and in some example embodiments, the slit 5411 may be formed to have a depth ranging from about 60% to about 70% of a thickness of the third substrate 5410.

In some example embodiments, as illustrated in a region ‘D2’, a conductive material 5412 may be formed in the slit 5411. For example, the conductive material 5412 may be used to discharge a leakage current occurring in driving of the circuit elements in the external pad bonding region PA to the outside. In this case, the conductive material 5412 may be connected to an external ground line.

In some example embodiments, as illustrated in a region ‘D3’, an insulating material 5413 may be formed in the slit 5411. For example, the insulating material 5413 may be used to electrically isolate the second input/output pad 5405 and the second input/output contact plug 5403 disposed in the external pad bonding region PA from the word-line bonding region WLBA. Since the insulating material 5413 is formed in the slit 5411, it is possible to prevent or reduce a voltage provided through the second input/output pad 5405 from affecting a metal layer disposed on the third substrate 5410 in the word-line bonding region WLBA.

Meanwhile, in some example embodiments, the first to third input/output pads 5205, 5405 and 5406 may be selectively formed. For example, the memory device 5000 may be realized to include only the first input/output pad 5205 disposed on the first substrate 5210, to include only the second input/output pad 5405 disposed on the third substrate 5410, or to include only the third input/output pad 5406 disposed on the upper insulating layer 5401.

In some example embodiments, at least one of the second substrate 5310 of the first cell region CREG1 and the third substrate 5410 of the second cell region CREG2 may be used as a sacrificial substrate and may be completely or partially removed before or after a bonding process. An additional layer may be stacked after the removal of the substrate. For example, the second substrate 5310 of the first cell region CREG1 may be removed before or after the bonding process of the peripheral circuit region PREG and the first cell region CREG1, and then, an insulating layer covering a top surface of the common source line 5320 or a conductive layer for connection may be formed. Likewise, the third substrate 5410 of the second cell region CREG2 may be removed before or after the bonding process of the first cell region CREG1 and the second cell region CREG2, and then, the upper insulating layer 5401 covering a top surface of the common source line 5420 or a conductive layer for connection may be formed.

FIG. 26 is a diagram illustrating a manufacturing process of a stacked semiconductor device according to some example embodiments.

Referring to FIG. 26, respective integrated circuits may be formed on a first wafer WF1 and a second wafer WF2. The memory cell array may be formed in the first wafer WF1, and the peripheral circuits may be formed in the second wafer WF2.

After the various integrated circuits have been respectively formed on the first and second wafers WF1 and WF2, the first wafer WF1 and the second wafer WF2 may be bonded together. The bonded wafers WF1 and WF2 may then be cut (or divided) into separate chips, in which each chip corresponds to a semiconductor device such as, for example, the memory device 6000, including a first semiconductor die SD1 and a second semiconductor die SD2 that are stacked vertically (e.g., the first semiconductor die SD1 is stacked on the second semiconductor die SD2, etc.). Each cut portion of the first wafer WF1 corresponds to the first semiconductor die SD1, and each cut portion of the second wafer WF2 corresponds to the second semiconductor die SD2. For example, the memory device 5000 of FIG. 25 may be manufactured based on the manufacturing process of FIG. 26.

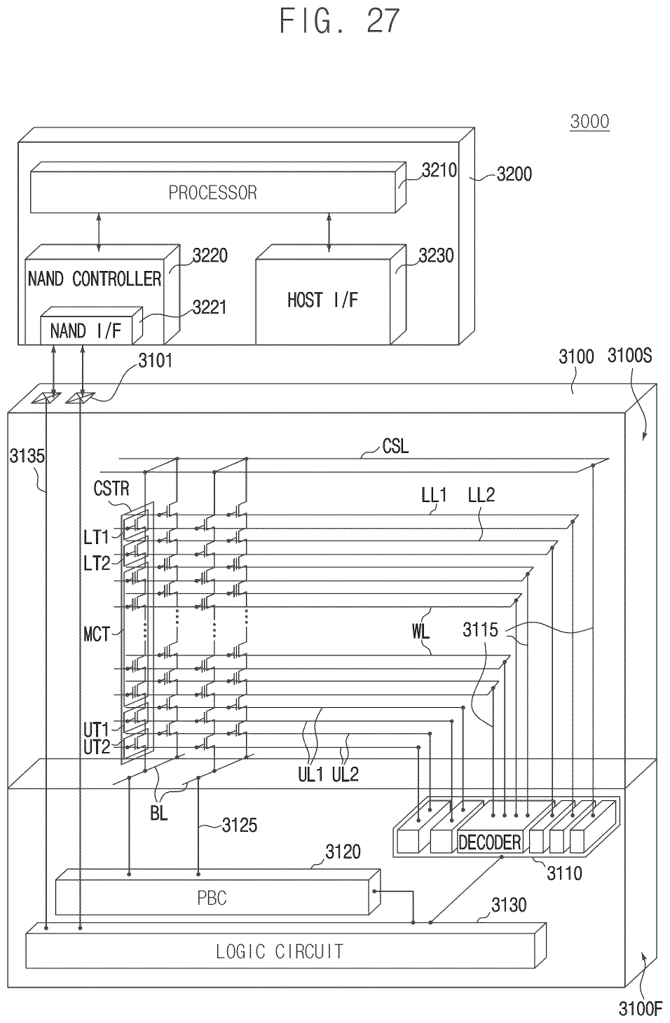

FIG. 27 is a block diagram illustrating an electronic system including a semiconductor device according to some example embodiments.

Referring to FIG. 27, an electronic system 3000 may include a semiconductor device 3100 and a controller 3200 electrically connected to the semiconductor device 3100. The electronic system 3000 may be a storage device including one or a plurality of semiconductor devices 3100 or an electronic device including a storage device. For example, the electronic system 3000 may be a solid state drive (SSD) device, a universal serial bus (USB), a computing system, a medical device, or a communication device that may include one or a plurality of semiconductor devices 3100.

The semiconductor device 3100 may be or may include a non-volatile memory device, for example, a nonvolatile memory device that is illustrated with reference to FIGS. 8 to 24. The semiconductor device 3100 may include a first structure 3100F and a second structure 3100S on the first structure 3100F. The first structure 3100F may be a peripheral circuit structure including a decoder circuit 3110, a page buffer circuit (PBC) 3120, and a logic circuit 3130. The second structure 3100S may be a memory cell structure including a bit-line BL, a common source line CSL, word-lines WL, first and second upper gate lines UL1 and UL2, first and second lower gate lines LL1 and LL2, and memory cell strings CSTR between the bit line BL and the common source line CSL.

In the second structure 3100S, each of the memory cell strings CSTR may include lower transistors LT1 and LT2 adjacent to the common source line CSL, upper transistors UT1 and UT2 adjacent to the bit-line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be varied in accordance with example embodiments.

In some example embodiments, the upper transistors UT1 and UT2 may include string selection transistors, and the lower transistors LT1 and LT2 may include ground selection transistors. The lower gate lines LL1 and LL2 may be gate electrodes of the lower transistors LT1 and LT2, respectively. The word lines WL may be gate electrodes of the memory cell transistors MCT, respectively, and the upper gate lines UL1 and UL2 may be gate electrodes of the upper transistors UT1 and UT2, respectively.

In some example embodiments, the lower transistors LT1 and LT2 may include a lower erase control transistor LT1 and a ground selection transistor LT2 that may be connected with each other in serial. The upper transistors UT1 and UT2 may include a string selection transistor UT1 and an upper erase control transistor UT2. At least one of the lower erase control transistor LT1 and the upper erase control transistor UT2 may be used in an erase operation for erasing data stored in the memory cell transistors MCT through gate induced drain leakage (GIDL) phenomenon.

The common source line CSL, the first and second lower gate lines LL1 and LL2, the word lines WL, and the first and second upper gate lines UL1 and UL2 may be electrically connected to the decoder circuit 3110 through first connection wirings 3115 extending to the second structure 3110S from the first structure 3100F. The bit-lines BL may be electrically connected to the page buffer circuit 3120 through second connection wirings 3125 extending to the second structure 3100S from the first structure 3100F.

In the first structure 3100F, the decoder circuit 3110 and the page buffer circuit 3120 may perform a control operation for at least one selected memory cell transistor among the plurality of memory cell transistors MCT. The decoder circuit 3110 and the page buffer circuit 3120 may be controlled by the logic circuit 3130. The semiconductor device 3100 may communicate with the controller 3200 through an input/output pad 3101 electrically connected to the logic circuit 3130. The input/output pad 3101 may be electrically connected to the logic circuit 3130 through an input/output connection wiring 3135 extending to the second structure 3100S from the first structure 3100F.

The controller 3200 may include a processor 3210, a NAND controller 3220, and a host interface (I/F) 3230. The electronic system 3000 may include a plurality of semiconductor devices 3100, and in this case, the controller 3200 may control the plurality of semiconductor devices 3100.

The processor 3210 may control operations of the electronic system 3000 including the controller 3200. The processor 3210 may be operated by firmware, and may control the NAND controller 3220 to access the semiconductor device 3100. The NAND controller 3220 may include a NAND interface 3221 for communicating with the semiconductor device 3100. Through the NAND interface 3221, control command for controlling the semiconductor device 3100, data to be written in the memory cell transistors MCT of the semiconductor device 3100, data to be read from the memory cell transistors MCT of the semiconductor device 3100, etc., may be transferred. The host interface 3230 may provide communication between the electronic system 3000 and an outside host. When control command is received from the outside host through the host interface 3230, the processor 3210 may control the semiconductor device 3100 in response to the control command.

A nonvolatile memory device or a storage device according to example embodiments may be packaged using various package types or package configurations.

The present disclosure may be applied to various devices and systems that include the nonvolatile memory devices.

When the words “about”, “generally”, and “substantially” are used in connection with geometric shapes, it is intended that precision of the geometric shape is not required but that latitude for the shape is within the scope of the disclosure. Further, regardless of whether shapes are modified as “about” or “substantially,” it will be understood that these values and shapes should be construed as including a manufacturing or operational tolerance (e.g., +10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. A method of operating a nonvolatile memory device that includes at least one memory block including a plurality of cell strings, each of the plurality of cell strings including a string selection transistor, a plurality of memory cells, and a ground selection transistor connected in series in a vertical direction between a bit-line and a common source line, the method comprising:
detecting a voltage level of an external voltage provided from an external memory controller while receiving a read command sequence from the external memory controller;
setting up each of a plurality of word-lines coupled to the plurality of memory cells to a respective target level during a word-line set-up period while adaptively adjusting a ramping period during which a read pass voltage ramps to a target level based on the detected voltage level;
performing a sensing operation on target memory cells by applying a read voltage to a selected word-line coupled to the target memory cells, among the plurality of word-lines while applying the read pass voltage to unselected word-lines among the plurality of word-lines during a sensing period; and
outputting sensed data obtained by the sensing operation.

2. The method of claim 1, wherein the adaptively adjusting the ramping period includes:
adaptively adjusting a period of applying a pre-pulse to the unselected word-lines based on the detected voltage level during the word-line set-up period and at least one reference level.

3. The method of claim 2, wherein the adaptively adjusting the period of applying the pre-pulse includes:
applying the pre-pulse to the unselected word-lines during a first time interval in response to the detected voltage level being equal to or greater than the at least one reference level; and
applying the pre-pulse to the unselected word-lines during a second time interval greater than the first time interval, in response to the detected voltage level being smaller than the at least one reference level.

4. The method of claim 2, wherein the adaptively adjusting the period of applying the pre-pulse includes:
enabling a voltage generator that generates the pre-pulse during a first time interval in response to the detected voltage level being equal to or greater than the at least one reference level; and
enabling the voltage generator during a second time interval greater than the first time interval, in response to the detected voltage level being smaller than the at least one reference level.

5. The method of claim 2, wherein the adaptively adjusting the period of applying the pre-pulse includes:
turning-on a switch that transfers the pre-pulse to the unselected word-line during a first time interval in response to the detected voltage level being equal to or greater than the at least one reference level; and
turning-on the switch during a second time interval greater than the first time interval, in response to the detected voltage level being smaller than the at least one reference level.

6. The method of claim 1, wherein
the read command sequence includes a first read command, an address, and a second read command that are received sequentially from the external memory controller; and
the voltage level of the external voltage is detected while the address and the second read command are being received.

7. The method of claim 1, further comprising:
recovering a voltage level each of the unselected word-lines to an off level while outputting the sensed data.

8. A nonvolatile memory device comprising:
a memory cell array that includes at least one memory block including a plurality of cell strings, each of the plurality of cell strings including a string selection transistor, a plurality of memory cells, and a ground selection transistor connected in series in a vertical direction between a bit-line and a common source line; and
a control circuit configured to control a read operation by,
detecting a voltage level of an external voltage provided from an external memory controller while receiving a read command sequence from the external memory controller;
setting up each of a plurality of word-lines coupled to the plurality of memory cells to a respective target level during a word-line set-up period while adaptively adjusting a ramping period during which a read pass voltage ramps to a target level based on the detected voltage level;
performing a sensing operation on target memory cells by applying a read voltage to a selected word-line coupled to the target memory cells, among the plurality of word-lines while applying the read pass voltage to unselected word-lines among the plurality of word-lines during a sensing period; and
outputting sensed data obtained by the sensing operation.

9. The nonvolatile memory device of claim 8, further comprising:
a voltage generation circuit configured to generate word-line voltages including the read voltage and the read pass voltage based on control signals and external voltage;
a voltage detector configured to generate a level detection signal based on the detected voltage level and at least one reference level;
an address decoder configured to provide the word-line voltages to the at least one memory block based on a row address; and
a page buffer circuit coupled to the at least one memory block through a plurality of bit-lines, the page buffer circuit configured to latch the sensed data in the sensing operation.

10. The nonvolatile memory device of claim 9, wherein
the voltage generation circuit is further configured to generate a pre-pulse based on the control signals, and
the control circuit is configured to control the voltage generation circuit and the address decoder to adjust adaptively a period of applying the pre-pulse to the unselected word-lines during the word-line set-up period.

11. The nonvolatile memory device of claim 10, wherein the control circuit is configured to:
control the voltage generation circuit and the address decoder to apply the pre-pulse to the unselected word-lines during a first time interval, in response to the level detection signal indicating that the detected voltage level is equal to or greater than the at least one reference level; and
control the voltage generation circuit and the address decoder to apply the pre-pulse to the unselected word-lines during a second time interval greater than the first time interval, in response to the level detection signal indicating that the detected voltage level is smaller than the at least one reference level.

12. The nonvolatile memory device of claim 10, wherein
the voltage generation circuit includes:
a first voltage generator configured to generate the pre-pulse and the read pass voltage; and
a second voltage generator configured to generate the read voltage, and
the control circuit is configured to:
apply the pre-pulse to the unselected word-lines by enabling the first voltage generator during a first time interval, in response to the level detection signal indicating that the detected voltage level is equal to or greater than the at least one reference level; and
apply the pre-pulse to the unselected word-lines by enabling the first voltage generator during a second time interval greater than the first time interval, in response to the level detection signal indicating that the detected voltage level is smaller than the at least one reference level.

13. The nonvolatile memory device of claim 10, wherein
the address decoder includes:
a first switch configured to transfer the pre-pulse and the read pass voltage to the unselected word-lines; and
a second switch configured to transfer the read voltage to the selected word-line, and
the control circuit is configured to:
apply the pre-pulse to the unselected word-lines by turning-on the first switch during a first time interval, in response to the level detection signal indicating that the detected voltage level is equal to or greater than the at least one reference level; and
apply the pre-pulse to the unselected word-lines by turning-on the first switch during a second time interval greater than the first time interval, in response to the level detection signal indicating that the detected voltage level is smaller than the at least one reference level.

14. The nonvolatile memory device of claim 10, wherein the voltage generation circuit is configured to:
increase a voltage of each of the unselected word-lines from an off voltage to the read pass voltage by applying the pre-pulse to the unselected word-lines during the word-line set-up period; and
increase a voltage of the selected word-line from an off voltage to the read voltage.

15. The nonvolatile memory device of claim 14, wherein the control circuit is configured to control the voltage generation circuit based on the detected voltage level to adjust a time interval during which the voltage of each of the unselected word-lines arrives at the read pass voltage by adjusting a time interval during which the voltage generating circuit applying the pre-pulse to the unselected word-lines.

16. The nonvolatile memory device of claim 9, wherein:
the memory cell array is on a first semiconductor layer;
the control circuit, the voltage generation circuit, the address decoder, and the page buffer circuit are on a second semiconductor layer; and
the first semiconductor layer and the second semiconductor layer are vertically stacked.

17. The nonvolatile memory device of claim 9, wherein:
the control circuit is configured to receive a first read command, an address, and a second read command sequentially from the external memory controller as the read command sequence; and
the voltage detector is configured to detect the voltage level of the external voltage while the control circuit is receiving the address and the second read command.

18. The nonvolatile memory device of claim 8, wherein:
the control circuit is configured to adjust adaptively a time interval during which a status signal indicates a busy state, based on the detected voltage level, the status signal indicating an operating status of the nonvolatile memory device; and
the status signal indicates the busy state during the word-line set-up period and during the control circuit performs the sensing operation.

19. The nonvolatile memory device of claim 8, wherein the control circuit is configured to recover a voltage level of each of the unselected word-lines to off level while outputting the sensed data.

20. A nonvolatile memory device comprising:
a memory cell array that includes at least one memory block including a plurality of cell strings, each of the plurality of cell strings including a string selection transistor, a plurality of memory cells, and a ground selection transistor connected in series in a vertical direction between a bit-line and a common source line;
a voltage generation circuit configured to generate word-line voltages including a read voltage, a read pass voltage, and a pre-pulse based on control signals;
an address decoder configured to provide the word-line voltages to the at least one memory block based on a row address; and
a control circuit configured to control a read operation by:
detecting a voltage level of an external voltage provided from an external memory controller while receiving a read command sequence from the external memory controller;
setting up each of a plurality of word-lines coupled to the plurality of memory cells to a respective target level during a word-line set-up period while adaptively adjusting a ramping period during which the read pass voltage ramps to a target level by adjusting a time period of applying the pre-pulse, based on the detected voltage level;
performing a sensing operation on target memory cells by applying the read voltage to a selected word-line coupled to the target memory cells, among the plurality of word-lines while applying the read pass voltage to unselected word-lines among the plurality of word-lines during a sensing period; and
outputting sensed data obtained by the sensing operation.
